(19) United States
(12) Patent Application Publication
(10) Pub. No.: US 2026/0020344 A1
(43) Pub. Date: Jan. 15, 2026

(54) Array Substrate

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Tianmin Zhou, Beijing (CN); Yunping Di, Beijing (CN); Yujie Liu, Beijing (CN); Wei Yang, Beijing (CN); Kun Yang, Dongguan (CN); Lizhong Wang, Beijing (CN)

(21) Appl. No.: 18/994,851

(22) PCT Filed: May 31, 2024
(86) PCT No.: PCT/CN2024/096854

§ 371 Date: Jan. 15, 2025

(30) Foreign Application Priority Data
Jun. 2, 2023 (CN) 202310653873.1
Jun. 29, 2023 (CN) 202310786621.6

(51) Int. Cl. H10D 86/40; H10D 86/60

(52) U.S. Cl. CPC H10D 86/421; H10D 86/441; H10D 86/60

(57) ABSTRACT

An array substrate, has a display area and a peripheral area located at a periphery of the display area. The array substrate further includes a base; a first transistor, disposed on a side of the base and disposed in the display area. The first transistor includes a first semiconductor pattern and a first electrode structure disposed on a side of the first semiconductor pattern away from the base; a connecting electrode, disposed on a side of the first electrode structure away from the base, and electrically connected to the first semiconductor pattern. A first electrode, disposed on a side of the connecting electrode away from the base, and electrically connected to the connecting electrode. A second electrode, disposed on a side of the first electrode away from the base; where at least one of the connecting electrode and the first electrode structure includes a semiconductor material.

### CROSS-REFERENCE TO RELATED APPLICATIONS

This application is the United States national phase of International Patent Application No. PCT/CN2024/096854, filed May 31, 2024, and claims priority to Chinese Patent Application Nos. 202310653873.1, filed Jun. 2, 2023, and 202310786621.6, filed Jun. 29, 2023, the disclosures of which are hereby incorporated by reference in its entirety.

### BACKGROUND OF THE INVENTION

### Field of the Invention

The present disclosure relates to the field of display technologies, particularly to an array substrate.

### Description of Related Art

With the rise of the metaverse concept, the virtual reality technology (Virtual Reality; abbreviated as: VR) display products have been rapidly developed. Currently, VR display products with good display performance on the market typically use micro organic light-emitting display (Micro OLED) products with a pixel density (Pixels Per Inch; abbreviated as PPI) reaching 2000+. However, Micro OLED products are costly, difficult to process, and difficult to popularize.

A liquid crystal display panel has prominent advantages in terms of low manufacturing cost and manufacturing difficulty, thanks to a simpler pixel circuit structure of the liquid crystal display panel, and the pixel circuit containing fewer number of thin film transistors (such as one thin film transistor) and capacitors. The liquid crystal display panel has a good development prospect in an ultra-high pixel density (such as greater than or equal to 1000PPI).

### SUMMARY OF THE INVENTION

On the one hand, an array substrate is provided. The array substrate has a display area and a peripheral area located at a periphery of the display area. The array substrate further includes a substrate, a first transistor, a connecting electrode, a first electrode, and a second electrode. The first transistor is disposed on a side of the base and disposed in the display area. The first transistor includes a first semiconductor pattern and a first electrode structure disposed on a side of the first semiconductor pattern away from the base. The connecting electrode is disposed on a side of the first electrode structure away from the base, and electrically connected to the first semiconductor pattern. The first electrode is disposed on a side of the connecting electrode away from the base, and electrically connected to the connecting electrode. The second electrode is disposed on a side of the first electrode away from the base. Here, at least one of the connecting electrode and the first electrode structure includes a semiconductor material.

In some embodiments, the array substrate further includes a second transistor. The second transistor is located on a same side of the substrate as the first transistor, and disposed in the peripheral area, the second transistor includes a second semiconductor pattern and a third semiconductor pattern. The second semiconductor pattern includes a second channel area and two second pole areas located on two opposite sides of the second channel area. The third semiconductor pattern includes a third channel area and two third pole areas located on two opposite sides of the third channel area. The second channel area and the third channel area have an interval in a direction perpendicular to the base, and an orthographic projection of the second channel area on the base at least partially overlaps with an orthographic projection of the third channel area on the base. A second pole area and a third pole area, that are located on a same side of the second channel area and the third channel area, are electrically connected.

In some embodiments, the second semiconductor pattern includes a same material and is disposed on a same layer as the first semiconductor pattern. And/or, the third semiconductor pattern includes a same material and is disposed on a same layer as one of the connecting electrode and the first electrode structure which includes the semiconductor material.

In some embodiments, the second transistor further includes a second electrode structure, and the second electrode structure is disposed at least partially opposite to the second channel area, and disposed at least partially opposite to the third channel area.

In some embodiments, the connecting electrode includes the semiconductor material, and the third semiconductor pattern includes a same material and is disposed on a same layer as the connecting electrode.

In some embodiments, the second electrode structure includes a first sub-electrode disposed between the second semiconductor pattern and the third semiconductor pattern. The first sub-electrode is disposed opposite to the second channel area and the third channel area respectively, and an orthographic projection of the first sub-electrode on the base at least partially overlaps with projections of the second channel area and the third channel area on the base respectively.

In some embodiments, the first sub-electrode includes a same material and is disposed on a same layer as the first electrode structure.

In some embodiments, the second transistor further includes at least one adaptor pattern. The adaptor pattern is disposed between the second pole area and the third pole area that are close to each other, and electrically connected to the second pole area and the third pole area respectively. The adaptor pattern includes a same material and is disposed on a same layer as the first sub-electrode.

In some embodiments, the second electrode structure further includes a second sub-electrode disposed on a side of the second semiconductor pattern near the base. The second sub-electrode is disposed opposite to the second channel area, and an orthographic projection of the second sub-electrode on the base at least partially overlaps with an orthographic projection of the second channel area on the base.

In some embodiments, the orthographic projection of the second sub-electrode on the base covers orthographic projections of the second channel area and the third channel area on the base, and partially overlaps with an orthographic projection of at least one of the two second pole areas and the two third pole areas on the base. The orthographic projection of the second sub-electrode on the base further covers an orthographic projection of the first sub-electrode on the base, and a boundary of the orthographic projection of the second sub-electrode has an interval with a boundary of the orthographic projection of the first sub-electrode.

In some embodiments, the display area further includes a first signal line, and the first signal line is disposed on a side of the first semiconductor pattern near the base. The first semiconductor pattern includes a first channel area and two first pole areas located on two opposite sides of the first channel area, one of the two first pole areas is electrically connected to the connecting electrode, and another of the two first pole areas is electrically connected to the first signal line. The first signal line includes a same material and is disposed on a same layer as the second sub-electrode.

In some embodiments, the connecting electrode includes a first sub-connecting electrode and a second sub-connecting electrode, the second sub-connecting electrode is located on a side of the first sub-connecting electrode away from the base. The array substrate further includes a first insulating layer, a second insulating layer, a first planar layer and a second planar layer, and the array substrate further includes a first via-hole and a second via-hole. The first insulating layer is disposed between the first semiconductor pattern and the first electrode structure. The second insulating layer is disposed between the first electrode structure and the first sub-connecting electrode. The first via passes through the second insulating layer and the first insulating layer, and exposes a part area of the first semiconductor pattern. The first sub-connecting electrode includes a first portion and a second portion, the first portion passes through the first via-hole to electrically connect with the first semiconductor pattern, and the second portion is located on a surface of the second insulating layer away from the base. The first planar layer is disposed between the first sub-connecting electrode and the second sub-connecting electrode. The second via-hole passes through the first planar layer. The second via-hole exposes at least a part of the second portion, the second sub-connecting electrode passes through the second via-hole to connect with the second portion, and a part of the second sub-connecting electrode located within the second via-hole includes a slot recessed towards a side near the base. The second planar layer is disposed between the second sub-connecting electrode and the first electrode, and the second planar layer is disposed within the slot, and a surface of the second planar layer away from the base is roughly flush with a surface of the second sub-connecting electrode away from the base. Here, the third semiconductor pattern includes a same material and is disposed on a same layer as the first sub-connecting electrode.

In some embodiments, the first electrode structure includes an auxiliary electrode and an electrode portion, the electrode portion is located on a side of the auxiliary electrode away from the base, a material of the auxiliary electrode includes a semiconductor material, and the third semiconductor pattern includes a same material and is disposed on a same layer as the auxiliary electrode.

In some embodiments, the second electrode structure includes a third sub-electrode disposed on a side of the third semiconductor pattern away from the base, and a fourth sub-electrode disposed on a side of the second semiconductor pattern near the base. The third sub-electrode is disposed opposite to the third semiconductor pattern, and an orthographic projection of the third sub-electrode on the base at least partially overlaps with an orthographic projection of the third channel area on the base. The fourth sub-electrode is disposed opposite to the second semiconductor pattern, and an orthographic projection of the fourth sub-electrode on the base at least partially overlaps with an orthographic projection of the second channel area on the base.

In some embodiments, the third sub-electrode includes a same material and is disposed on a same layer as the electrode portion.

In some embodiments, the display area further includes a first signal line, the first signal line is disposed on a side of the first semiconductor pattern near the base. The first semiconductor pattern includes a first channel area and two first pole areas located on two opposite sides of the first channel area, one of the two first pole areas is electrically connected to the connecting electrode, and another of the two first pole areas is electrically connected to the first signal line. The first signal line includes a same material and is disposed on a same layer as the fourth sub-electrode.

In some embodiments, a third insulating layer is included between the auxiliary electrode and the electrode portion. The auxiliary electrode and the electrode portion are electrically connected in the display area; and/or, the auxiliary electrode and the electrode portion are electrically connected in the peripheral area.

In some embodiments, the array substrate further includes a first insulating layer, a second insulating layer, a first planar layer, and a second planar layer. The first insulating layer is disposed between the first semiconductor pattern and the first electrode structure. The second insulating layer and the first planar layer are disposed between the first electrode structure and the connecting electrode, and the first planar layer is located away from a side of the base, compared to the second insulating layer. The third via-hole passes through the first planar layer, the second insulating layer, the third insulating layer and the first insulating layer, and exposes a part area of the first semiconductor pattern. The connecting electrode includes a third portion and a fourth portion, the third portion passes through the third via-hole to electrically connect with the first semiconductor pattern, and the fourth portion is located on a surface of the first planar layer away from the base and electrically connected to the first electrode. The third portion includes a slot recessed towards a side near the base, the second planar layer is disposed between the connecting electrode and the first electrode, and the second planar layer is disposed within the slot, and a surface of the second planar layer away from the base is roughly flush with a surface of the fourth portion away from the base.

In some embodiments, the second semiconductor pattern and the third semiconductor pattern both include a metal oxide semiconductor material. Electron mobility of the second semiconductor pattern is greater than electron mobility of the third semiconductor pattern, and light stability of the third semiconductor pattern is greater than light stability of the second semiconductor pattern.

In some embodiments, the second semiconductor pattern includes a high-mobility metal oxide semiconductor material; and/or, the third semiconductor pattern includes indium gallium zinc oxide.

In some embodiments, the array substrate further includes a third transistor. The third transistor is disposed on a side of the first transistor near the base and disposed in the peripheral area; the third transistor includes a fourth semiconductor pattern and a third electrode structure, the third electrode structure is located on a side of the fourth semiconductor pattern away from the base. Here, the fourth semiconductor pattern and the first semiconductor pattern include different semiconductor materials.

In some embodiments, the first transistor is an oxide thin-film transistor; and/or, the third transistor is a low-temperature poly silicon thin-film transistor.

In some embodiments, the array substrate further includes a first signal line, a buffer layer, and a fourth via-hole. The first signal line is disposed in the display area and disposed on a side of the first semiconductor pattern near the base. The buffer layer is disposed between the first signal line and the first semiconductor pattern. The fourth via-hole passes through the buffer layer, and exposes a part of the first signal line. Here, a part of the first semiconductor pattern is located within the fourth via-hole and passes through the fourth via-hole to electrically connect with the first signal line.

In some embodiments, the fourth via-hole exposes two opposite sidewalls of the first signal line, and an orthographic projection of the first semiconductor pattern on the base covers at least a half of an orthographic projection of the fourth via-hole on the base.

In some embodiments, the buffer layer includes a first sub-layer and a second sub-layer stacked along a direction away from the base; a material of the first sub-layer includes silicon nitride, and a material of the second sub-layer includes silicon oxide.

In some embodiments, a thickness of the first sub-layer is greater than or equal to 50 nm. And/or the array substrate further includes a first insulating layer. The first insulating layer is disposed between the first semiconductor pattern and the first electrode structure, and a thickness of the first insulating layer is 80 nm to 150 nm.

In some embodiments, in a case where the array substrate includes a third transistor, a third electrode structure includes a same material and is disposed on a same layer as the first signal line.

In some embodiments, the array substrate further includes multiple opening areas, and an opening area of the multiple opening areas is configured to form a light-emitting area of a sub-pixel. In addition, the array substrate further includes multiple lens structures and a third planar layer. The multiple lens structures are disposed on a side of the first transistor near the base, a lens structure of the multiple lens structures is configured to converge light emitted towards the lens structure; and a lens structure of the multiple lens structures covers at least one of the multiple opening areas. The third planar layer is disposed between the lens structure and the first transistor. A refractive index of the lens structure is greater than a refractive index of the third planar layer.

In some embodiments, the refractive index of the lens structure is 1.8 to 2.3; and/or, the refractive index of the third planar layer is 1.3 to 1.5.

In some embodiments, a thickness of the lens structure is 800 nm to 1500 nm; and/or, a thickness of the third planar layer is 1.5 μm to 2.5 μm.

In some embodiments, a lens structure of the multiple lens structures covers an opening area of the multiple opening areas; and/or, the array substrate includes multiple pixel units, a pixel unit of the multiple pixel units includes at least two opening areas for emitting different light; and a lens structure of the multiple lens structures covers the at least two opening areas of a pixel unit of the multiple pixel units.

In some embodiments, an orthographic projection of the lens structure on the base at least partially overlaps with an orthographic projection of a first signal line on the base.

In some embodiments, along a first direction, two adjacent lens structures of the multiple lens structures are connected to each other; and/or, along a second direction, there is an interval between two adjacent lens structures of the multiple lens structures.

On the other hand, a display apparatus is provided. The display apparatus includes the array substrate as described in any one of the above embodiments.

### BRIEF DESCRIPTION OF THE DRAWINGS

The terms Fig., Figs., Figure, and Figures are used interchangeably in the specification to refer to the corresponding figures in the drawings.

In order to describe technical solutions in the present disclosure more clearly, drawings to be used in some embodiments of the present disclosure will be introduced briefly, and obviously, the drawings in the following description are merely drawings of some embodiments of the present disclosure, and those ordinary skilled in the art may further obtain other drawings according to these drawings. In addition, the drawings in the following description may be regarded as schematic diagrams, and are not limitations on an actual size of a product, an actual procedure of a method and an actual timing of a signal, etc., involved in the embodiments of the present disclosure.

FIG. 1A is a plane structure diagram of a display apparatus according to some embodiments.

FIG. 1B is a schematic diagram of an overall structure of an AR/VR/MR display product according to some embodiments.

FIG. 1C is a schematic diagram of a composition structure of an AR/VR/MR display product according to some embodiments.

FIG. 2 is a diagram of a composition structure of a display apparatus according to some embodiments.

FIG. 3A is a plane structure diagram of a display area of an array substrate according to some embodiments.

FIG. 3B is another plane structure diagram of a display area of an array substrate according to some embodiments.

FIG. 4A is a sectional structure diagram of a display area of an array substrate according to some embodiments.

FIG. 4B is a sectional structure diagram of a display area of an array substrate according to some embodiments.

FIG. 5 is a structure diagram of a second transistor of an array substrate according to some embodiments.

FIG. 6 is a diagram of a relationship between a channel length and a threshold voltage of a metal oxide thin film transistor.

FIG. 7 is another structure diagram of a second transistor of an array substrate according to some embodiments.

FIG. 8 is yet another structure diagram of a second transistor of an array substrate according to some embodiments.

FIG. 9 is a sectional structure diagram of an array substrate according to some embodiments.

FIG. 10 is a sectional structure diagram of an array substrate according to some embodiments.

FIG. 11 is yet another plane structure diagram of a display area of an array substrate according to some embodiments.

FIG. 12 is yet another plane structure diagram of a display area of an array substrate according to some embodiments.

FIG. 13 is another sectional structure diagram of an array substrate according to some embodiments.

FIG. 14 is a structure diagram of a first signal line when the first signal line is located above a first semiconductor pattern.

FIG. 15 is a structure diagram of a lens structure and an opening area according to some embodiments.

FIG. 16 is another structure diagram of a lens structure and an opening area according to some embodiments.

FIG. 17 is another sectional structure diagram of an array substrate according to some embodiments.

FIG. 18 is another sectional structure diagram of an array substrate according to some embodiments.

FIG. 19A to FIG. 19F are diagrams of a manufacturing process of an array substrate according to some embodiments.

### DESCRIPTION OF THE INVENTION

The technical solutions in some embodiments of the present disclosure will be described clearly and completely with reference to the drawings; obviously, the described embodiments are merely some but not all of the embodiments of the present disclosure. All other embodiments obtained by those ordinary skilled in the art based on the embodiments provided in the present disclosure shall be included in the protection scope of the present disclosure.

Throughout the specification and the claims, the term “comprise/include” and other forms thereof such as the third-person singular form “comprises/includes” and the present participle form “comprising/including” are construed as an open and inclusive meaning, i.e., “including, but not limited to”, unless the context requires otherwise. In the description of the specification, the terms such as “one embodiment”, “some embodiments”, “exemplary embodiments”, “example”, “specific example”, or “some examples”, etc., are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the described specific features, structures, materials, or characteristics may be included in any one or more embodiments or examples in any suitable manner.

In the present disclosure, terms such as “under”, “below”, “above” and “over”, or the like, are used to explain the relationship association of components shown in the drawings. Terms may be relative concepts, and described based on the direction indicated in the drawings or described in sequence formed by process steps, but not limited thereto.

The term “relative” means that a first element may be directly or indirectly relative to a second element. In a case where a third element is located between the first element and the second element, although they are still relative to each other, the first element and the second element may be understood as being indirectly relative to each other.

Hereinafter, the terms “first” and “second”, etc., are only used for descriptive purposes, and cannot be construed as indicating or implying the relative importance or implicitly indicating the number of indicated technical features. Thus, a feature defined by “first” or “second”, etc., may explicitly or implicitly include one or more of this feature. In the description of the embodiments of the present disclosure, the term “a/the plurality of” or “multiple” means two or more, unless described otherwise.

In the description of some embodiments, the expressions “coupled”, “connected” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates that, for example, two or more components are in direct physical or electrical contact with each other. The terms “coupled” or “communicatively coupled” may also mean that two or more components are not in direct contact with each other, but still coordinate or interact with each other. The embodiments disclosed herein are not necessarily limited to the content herein.

The phrase “at least one of A, B, and C” has the same meaning as the phrase “at least one of A, B, or C”, both including the following combinations about A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The use of “applicable to” or “configured to” herein indicates an open and inclusive expression, which does not exclude devices that are applicable to or configured to perform additional tasks or steps.

In addition, the use of the phrase “based on/on the basis of” is meant to be open and inclusive, since a process, step, calculation or other actions that is “based on” one or more of the stated conditions or values may, in practice, be based on additional conditions or values other than those stated.

The term such as “about”, “roughly”, or “approximately” as used herein includes a stated value and an average value within an acceptable deviation range of a particular value, where the acceptable deviation range is determined by those ordinary skilled in the art, considering the measurement(s) in question and error(s) related to the measurement(s) of a particular quantity (i.e., limitation(s) of a measurement system).

The term such as “parallel”, “perpendicular”, or “equal” as used herein includes a stated case and a case similar to the stated case. A range of the similar case is within an acceptable deviation range, where the acceptable deviation range is determined by those ordinary skilled in the art, considering the measurement(s) in question and error(s) related to the measurement(s) of a particular quantity (i.e., limitation(s) of a measurement system). For example, the term “parallel” includes absolute parallelism and approximate parallelism, where an acceptable deviation range of the approximate parallelism may be, for example, a deviation within 5°; the term “perpendicular” includes absolute perpendicularity and approximate perpendicularity, where an acceptable deviation range of the approximate perpendicularity may also be, for example, a deviation within 5°. The term “equal” includes absolute equality and approximate equality, where an acceptable deviation range of the approximate equality may be that, for example, a difference value between the equal two is less than or equal to 5% of any one of the two.

It should be understood that, when a layer or element is referred to as being on another layer or substrate, the layer or element may be directly on the another layer or substrate, or intervening layer(s) may exist between the layer or element and the another layer or substrate.

Exemplary implementations are described herein with reference to section views and/or plane views that are idealized and exemplary drawings. In the drawings, thicknesses of layers and sizes of areas are enlarged for clarity. Thus, variations in shape with respect to the drawings due to, for example, manufacturing technologies and/or tolerances, may be envisaged. Therefore, the exemplary implementations should not be construed as being limited to the shapes of the areas shown herein, but should include shape deviations due to, for example, manufacturing. For example, an etched area shown in a rectangular shape generally has a curved feature. Therefore, the areas shown in the drawings are schematic in nature, and their shapes are not intended to show actual shapes of the areas in a device, and are not intended to limit the scope of the exemplary implementations.

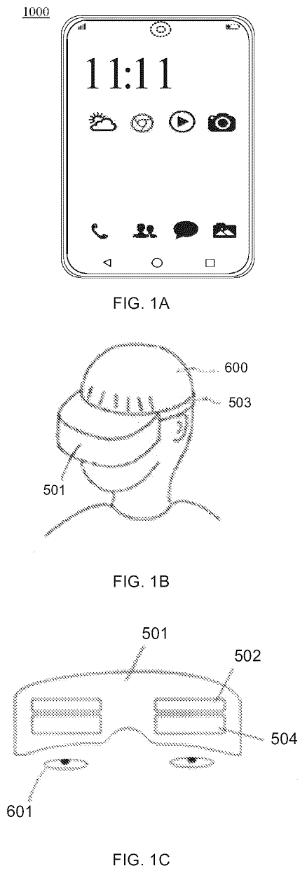

Referring to FIG. 1A, the embodiments of the present disclosure provide a display apparatus, and the display apparatus 1000 is a product with an image display function. Exemplarily, the display apparatus 1000 may be any apparatus that displays either motions (e.g., videos) or stationary (e.g., still images) and either texts or images.

In some embodiments, the aforementioned display apparatus may be an augmented reality (Augmented Reality, abbreviated as: AR) device, a virtual reality (Virtual Reality, abbreviated as: VR) device, or a mixed reality (Mixed Reality, abbreviated as: MR) device. Alternatively, in some other embodiments, the aforementioned display apparatus may also be a television, a laptop computer, a tablet computer, a personal digital assistant (Personal Digital Assistant, abbreviated as: PDA), a mobile phone (cellphone), a watch, a clock, a calculator, a global position system (GPS) receiver/navigator, a camera, a display of a camera view (such as a display of a rear view camera in a vehicle), a wearable device, an in-vehicle display, a flight display, or any other product or component with a display function.

Exemplarily, referring to FIG. 1B and FIG. 1C, when the aforementioned display apparatus is an AR/MR/VR display product, the display apparatus 1000 may include a casing 501 and a wearable structure 503. The wearable structure 503 may be worn on a body of a user/consumer 600, such as worn on the user's head. The casing 501 is used to carry and install display components, and the display components may include, for example, a display backboard (also known as a display panel) 502 and an optical assembly 504. Light emitted from the display backboard 502 is processed by the optical assembly 504 and then emitted into user's eyes 601.

In some embodiments, from the perspective of the light-emitting type of the display apparatus 1000, the aforementioned display apparatus 1000 may be a liquid crystal display apparatus (Liquid Crystal Display, abbreviated as LCD). From the perspective of the driving type of the display apparatus, and from the perspective of the form of the display apparatus 1000, the aforementioned display apparatus 1000 may be a planar display apparatus or a curved display apparatus, etc. From the perspective of the shape of the display apparatus 1000, the aforementioned display apparatus 1000 may be rectangular or circular, etc. Below, taking the display apparatus being a rectangular and planar liquid crystal display apparatus as an example, some embodiments of the present disclosure are illustrated schematically, but the implementations of the present disclosure are not limited thereto, and any other display apparatuses may also be considered as long as the same technical idea is applied.

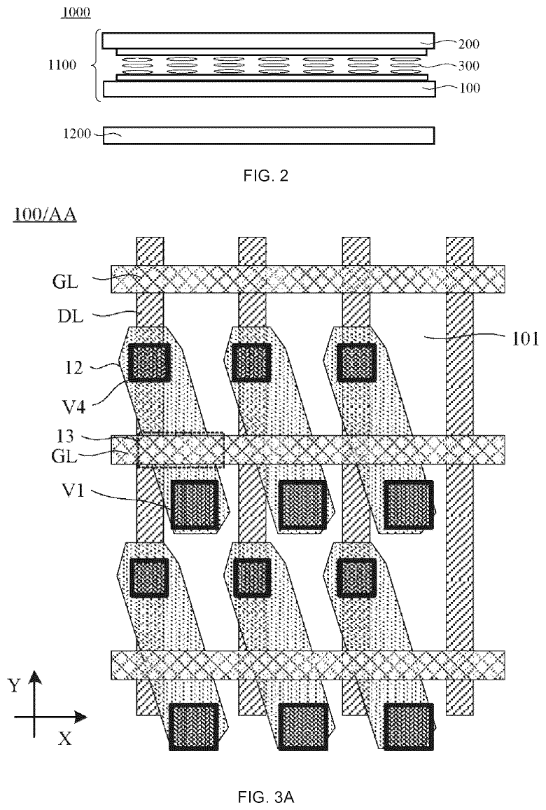

In some embodiments, referring to FIG. 2, the display apparatus 1000 includes a display panel 1100 and a driving circuit board (not shown in the figure). The driving circuit board may include, for example, a timing controller (Timing Controller, abbreviated as: TCON), a power management chip (DC/DC), and an adjustable resistance voltage division circuit (generating Vcom), or other driving circuits. The driving circuit board may also include other circuit structures, which are not listed here one by one. The driving circuit board is electrically connected to the display panel 1100, for transmitting control signals to the display panel 1100, thereby driving the display panel 1100 to achieve the image display. In addition, the display apparatus 1000 may also include a touch structure, a camera, and an under-screen fingerprint identification sensor, etc., enabling the display apparatus 1000 to achieve multiple different functions such as touch, photography, video recording, or fingerprint identification, etc., which are not listed here one by one.

Continuing to refer to FIG. 2, in a case where the display apparatus 1000 is a liquid crystal display apparatus, the display apparatus 1000 may also include a backlight source 1200 disposed on a backlight side of the display panel 1100. Exemplarily, the backlight source 1200 may be a direct backlight source or edge backlight source, etc. The backlight source 1200 is used to provide the light source for the display panel 1100, the display panel 1100 includes multiple sub-pixels, and each of the sub-pixels may adjust the amount of light passing through the display panel 1100, thereby enabling each sub-pixel to display the same or different gray levels, to achieve the image display.

Continuing to refer to FIG. 2, in a case where the display panel 1100 is a liquid crystal display panel, the display panel 1100 may include an array substrate 100 and a color film substrate 200 that are disposed oppositely, as well as a liquid crystal layer 300 disposed between the array substrate 100 and the color film substrate 200, where the color film substrate 200 may also be referred to as an opposite substrate or encapsulation substrate. The color film substrate 200 may filter the light emitted into the color film substrate 200, so that each sub-pixel emits light of one colour (e.g., red, green or blue), and different sub-pixels may emit light of the same or different colors, thereby enabling the display panel 1100 to achieve the color display. The structure of the display panel 1100 is not limited thereto, and the display panel 1100 may also include other structures as long as the same technical idea is used. For example, the display panel 1100 may also include a first alignment film (not shown in the figure) disposed on a side of the array substrate 100 near the liquid crystal layer 300, and a second alignment film (not shown in the figure) disposed on a side of the color film substrate 200 near the liquid crystal layer 300.

In some embodiments, the array substrate 100 may include a display area AA, and a peripheral area BB surrounding the display area AA. The display area AA may include multiple pixel circuits, pixel electrodes, and common electrodes, and the peripheral area may include, for example, a gate driving circuit (Gate Driver On Array; abbreviated as GOA), which is configured to drive the pixel circuit.

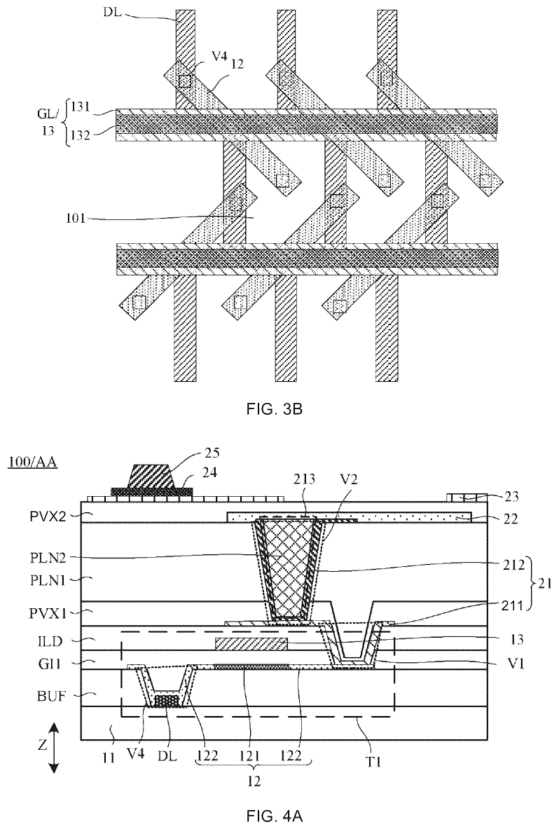

Referring to FIG. 3A and FIG. 3B, the display area AA includes multiple first signal lines DL and multiple second signal lines GL. The multiple first signal lines DL are distributed at intervals along a first direction X, and extend overall along a second direction Y. The multiple second signal lines GL are distributed at intervals along the second direction Y, and extend overall along the first direction X. The multiple first signal lines DL and the multiple second signal lines GL intersect mutually to form grid structures, where each grid structure defines a pixel area 101. Here, the first signal lines DL may be straight lines (as shown in FIG. 3A) or broken lines (as shown in FIG. 3B) in their extending direction, and/or, the second signal lines GL may be straight lines (as shown in FIG. 3A and FIG. 3B) or broken lines (not shown in the figure) in their extending direction. The first direction X and the second direction Y intersect mutually, and exemplarily, the first direction X and the second direction Y are perpendicular to each other.

A pixel area 101 may include a pixel circuit, and the pixel circuit may include at least one thin film transistor (Thin Film Transistor; abbreviated as: TFT) and at least one capacitor. Exemplarily, the pixel circuit may be a “1T1C” circuit or a “2T1C” circuit, etc. Here, “T” refers to the thin film transistor, and the number preceding “T” refers to the number of thin film transistors; “C” refers to the capacitor, and the number preceding “C” refers to the number of capacitors.

In the following embodiments of the present disclosure, taking the pixel circuit being a “1T1C” circuit as an example, the embodiments of the present disclosure are described exemplarily, but the embodiments of the present disclosure are not limited thereto, and any other pixel circuit may also be considered as long as the same technical idea is applied. In a case where the pixel circuit is a “1T1C” circuit, the pixel circuit may include a first transistor T1 and a first capacitor Cst. The “1T1C” circuit may significantly reduce the number of thin film transistors included in the pixel circuit, and reduce the space occupied by the pixel circuit, which is beneficial for improving the aperture ratio of the array substrate, thereby improving the pixel density of the array substrate.

In some embodiments, the first transistor T1 may be an oxide thin-film transistor (Oxide Thin-film transistor, abbreviated as: OTFT). The oxide thin-film transistor has a characteristic of low leakage current, which is beneficial for reducing the leakage current of the first transistor T1, thereby simplifying the circuit structure of the pixel circuit, and thus improving the aperture ratio of the array substrate 100 and improving the light transmittance of the array substrate 100.

The relevant technologies provide an array substrate, where a gate driving circuit in a peripheral area of the array substrate includes a second transistor, and the second transistor is also taking an oxide thin-film transistor. However, the applicants have found that, compared to the low temperature polycrystalline silicon (Low Temperature Poly-Silicon; abbreviated as: LTPS) thin-film transistor, the electron mobility of the oxide thin-film structure is relatively lower, and based on this, the conventional structure of the gate driving circuit using the oxide thin-film transistor is relatively complex, such as a gate driving circuit of 18T3C is required, which results in an increase in the size occupied by the gate driving circuit, and affects the width of the peripheral area of the array substrate, which is not conducive to the narrow border design of the display apparatus. How to improve the on-state current and stability of the thin film transistor of the peripheral area is an urgent technical issue that needs to be solved currently.

In order to solve the above problems, some embodiments of the present disclosure provide an array substrate 100, referring to FIG. 4A and FIG. 4B, the array substrate 100 includes a base 11, a first transistor T1, a connecting electrode 21, a first electrode 22 and a second electrode 23.

The first transistor T1 is disposed on the base 11 and disposed within the display area AA. The first transistor T1 includes a first semiconductor pattern 12, and a first electrode structure 13 disposed on a side of the first semiconductor pattern 12 away from the base.

Exemplarily, the first semiconductor pattern 12 may include two first pole areas 122 and a first channel area 121 located between the two first pole areas 122. The first channel area 121 is configured to form a channel of the first transistor T1, one of the two first pole areas 122 is configured to form a source connection area of the first transistor T1, and another of the two first pole areas 122 is configured to form a drain connection area of the first transistor T1. The first electrode structure 13 is configured to be electrically connected to the second signal line GL, or at least a part of the second signal line GL forms the first electrode structure 13, and an orthographic projection of the first electrode structure 13 on the base 11 covers an orthographic projection of the first channel area 121 on the base 11, for forming a gate (control electrode) of the first transistor T1. One of the two first pole areas 122 is configured to be electrically connected to the first signal line DL, and another of the two first pole areas 122 is configured to be electrically connected to the first electrode 22, and for example, as shown in FIG. 4A, the first pole area 122 located on the left is configured to be electrically connected to the first signal line DL, and the first pole area 122 located on the right is configured to be electrically connected to the first electrode 22 through the connecting electrode 21.

The connecting electrode 21 is disposed on a side of the first electrode structure 13 away from the base 11, and is electrically connected to the first semiconductor pattern 12. Here, the connecting electrode 21 being disposed on the side of the first electrode structure 13 away from the base 11, means that a film layer in which the connecting electrode 21 is located, is formed after a film layer in which the first electrode structure 13 is located, and in terms of the spatial structure, the connecting electrode 21 is not always located on the side of the first electrode structure 13 away from the base 11. Exemplarily, the array substrate 100 also includes a first insulating layer GI1 located between the first semiconductor pattern 12 and the first electrode structure 13, a second insulating layer ILD located between the first electrode structure 13 and the connecting electrode 21, and a first via-hole V1 passing through the first insulating layer GI1 and the second insulating layer ILD, a part of the connecting electrode 21 is disposed on a surface of the first insulating layer GI1 and is spatially located on a side of the first electrode structure 13 away from the base 11, and another part of the connecting electrode 21 is located within the first via-hole V1 and is electrically connected to the first semiconductor pattern 12 through the first via-hole V1, such as the connecting electrode 21 is electrically connected to a first pole area 122 of the first semiconductor pattern 12.

In some embodiments, as shown in FIG. 3A, FIG. 3B, and FIG. 4A, an orthographic projection of the first via-hole V1 on the base 11 is located within an orthographic projection of the pixel area 101 on the base 11. Exemplarily, the orthographic projection size of the pixel area 101 on the base 11 is larger than the orthographic projection size of the first via-hole V1 on the base 11, and the orthographic projection of the pixel area 101 on the base 11 covers the orthographic projection of the first via-hole V1 on the base 11. Of course, in some other embodiments, the first via-hole V1 may also not be located in the pixel area 101; or, the first via-hole V1 is partially located in the pixel area 101 and is partially located outside the pixel area 101.

The first electrode 22 is disposed on a side of the connecting electrode 21 away from the base 11, and is electrically connected to the connecting electrode 21. The second electrode 23 is disposed on a side of the first electrode 22 away from the base 11. The first electrode 22 is electrically connected to a first pole area 122 of the first semiconductor pattern 12 through the connecting electrode 21, and exemplarily, the first electrode 22 may be a pixel electrode. The second electrode 23 is configured to be electrically connected to a constant voltage signal, and the second electrode 23 may be a common electrode. Between the first electrode 22 and the second electrode 23 is also used to form the first capacitor Cst.

Exemplarily, the second signal line GL controls the first transistor T1 to turn on or turn off, through the first electrode structure 13. In a case where the first electrode structure 13 controls the first transistor T1 to turn on, the first semiconductor pattern 12 of the first transistor T1 electrically connects the first signal line DL with the connecting electrode 21, thereby transmitting a voltage signal (such as a data signal) transmitted on the first signal line DL to the connecting electrode 21, and then through the connecting electrode 21, transmitting to the first electrode 22. An electric field is formed between the first electrode 22 and the second electrode 23, to drive liquid crystal molecules in the liquid crystal layer to deflect, thereby adjusting the gray level of the sub-pixel display.

In some embodiments, at least one of the connecting electrode 21 and the first electrode structure 13 includes a semiconductor material. That is, the array substrate 100 may form a structure including two layers of semiconductor materials, and based on this, the transistor with two semiconductor layers may be manufactured and formed in the peripheral area, and the transistor may include at least two conductive interfaces, which is conducive to improving the on-state current of the transistor, thereby reducing the size of the transistor, is conducive to simplifying the structure of the gate driving circuit, and thus reducing the space occupied by the gate driving circuit and reducing the width of the peripheral area, and is conducive to achieving a narrow border for the array substrate 100 and the display apparatus.

Exemplarily, the connecting electrode 21 includes a semiconductor material, and the first electrode structure 13 does not include a semiconductor material, and for example, the first electrode structure 13 includes a metallic conductive material. Alternatively, the first electrode structure 13 includes a semiconductor material, and the connecting electrode 21 does not include a semiconductor material. Since at least a part of the connecting electrode 21 is located within the pixel area 101, based on this, the connecting electrode 21 may include a transparent conductive material. Alternatively, both the connecting electrode 21 and the first electrode structure 13 include a semiconductor material.

It should be noted that in order to improve the conductivity of the connecting electrode 21 and the first electrode structure 13, at least one of the connecting electrode 21 and the first electrode structure 13 which includes a semiconductor material, may undergo a process (conductive process) that makes it more conductive. The process that makes them more conductive may be referred to the above and will not be repeated here.

In some embodiments, the first semiconductor pattern 12 may be manufactured by using various appropriate semiconductor materials and various appropriate manufacturing methods, or the material of the first semiconductor pattern 12 may include at least one of various appropriate semiconductor materials. In some embodiments, the semiconductor material includes M1OₐN_{b}, where M1 is a single metal or combination of multiple metals, a>0, and b≥0, O represents oxygen, N represents nitrogen, that is, the semiconductor material is a metal oxide material or a metal nitrogen-oxide material. The suitable metal oxide material includes but is not limited to one or more of: Indium Gallium Zinc Oxide (IGZO), Indium Gallium Tin Oxide (IGTO), Indium Tin Zinc Oxide (ITZO), Indium Gallium Oxide (IGO), Indium Gallium Zinc Tin Oxide (IGZTO), Indium Zinc Oxide (IZO), Zinc Tin Oxide (ZTO), Indium-free Metal Oxide (In-free OS), Rare Earth Doped Oxide (Ln-OS, such as rare earth element doped IGZO/IZO), Zinc Oxide (ZnO), Gallium Oxide (GaO), Indium Oxide (InO), HfInZnO (HIZO), ZnO:F, In₂O₃:Sn, In₂O₃:Mo, Cd₂SnO₄, ZnO:Al, TiO₂:N_{b} and Cd—Sn—O. The material of the first semiconductor pattern 12 may be in an amorphous, partially crystalline, single crystal or polycrystalline state, or may also be a single-layer or multi-layer structure.

The suitable metal nitrogen-oxide material includes but is not limited to zinc nitrogen-oxide, indium nitrogen-oxide, gallium nitrogen-oxide, tin nitrogen-oxide, cadmium nitrogen-oxide, aluminum nitrogen-oxide, germanium nitrogen-oxide, titanium nitrogen-oxide, silicon nitrogen-oxide, or combinations thereof.

In an embodiment, the material of the first semiconductor pattern 12 includes a high-mobility metal oxide semiconductor material (High Mobility Metal Oxide Semiconductor; abbreviated as: HMOS), which is conducive to increasing the electron mobility of the first semiconductor pattern 12, and improving the on-state current of the first transistor T1. Additionally, the high-mobility metal oxide semiconductor material also has good light stability, which is conducive to improving the light stability of the first transistor T1. The high-mobility metal oxide semiconductor material includes but is not limited to rare earth elements doped IZO and IGZO, with the doping concentration of rare earth elements ranging from 0.1% to 2%.

Here, the first pole area 122 and the first channel area 121 are of one-piece structure, and both the material of the first channel area 121 and the material of the first pole area 122 include M1OₐN_{b}. The difference between the first pole area 122 and the first channel area 121 lies in that the first pole area 122 undergoes the process (conductive process) that makes it more conductive. The conductivity of the first channel area 121 differs from the conductivity of the first pole area 122. Exemplarily, the first channel area 121 may include a semiconductor material, and the first pole area 122 may include the doped semiconductor material. In this way, the first pole area 122 may form a conductor, and the first channel area 121 forms a semiconductor.

In an example, when the materials of the first channel area 121 and the first pole area 122 both include M1OₐN_{b}, M1OₐN_{b} in the first pole area 122 undergoes a light doping process (for example, a light doping ion implantation process). In another example, when the materials of the first channel area 121 and the first pole area 122 include M1OₐN_{b}, M1OₐN_{b} in the first pole area 122 undergoes an annealing process. In another example, when the materials of the first channel area 121 and the first pole area 122 include M1OₐN_{b}, M1OₐN_{b} in the first pole area 122 undergoes an oxide supplement process. Exemplarily, the light doping process may be performed by using the doping concentration ranging about 1×10¹⁵ atoms/cm³ to about 1×10²⁰ atoms/cm³, for example, about 1×10¹⁵ atoms/cm³ to about 1×10¹⁶ atoms/cm³, about 1×10¹⁶ atoms/cm³ to about 1×10¹⁷ atoms/cm³, about 1×10¹⁷ atoms/cm³ to about 1×10¹⁸ atoms/cm³, about 1×10¹⁸ atoms/cm³ to about 1×10²⁰ atoms/cm³, and about 1×10¹⁹ atoms/cm³ to about 1×10²⁰ atoms/cm³. Exemplarily, the light doping process is performed by using an N-type dopant to enhance the conductivity. The N-type dopant may include, for example, an element of Group VA of the periodic table of elements, including but not limited to nitrogen (N), phosphorus (P), arsenic (As), antimony (Sb), and bismuth (Bi). The light doping process may also be performed by using a protective gas element, such as argon (Ar), helium (He), oxygen (O), hydrogen (H), and fluorine (F).

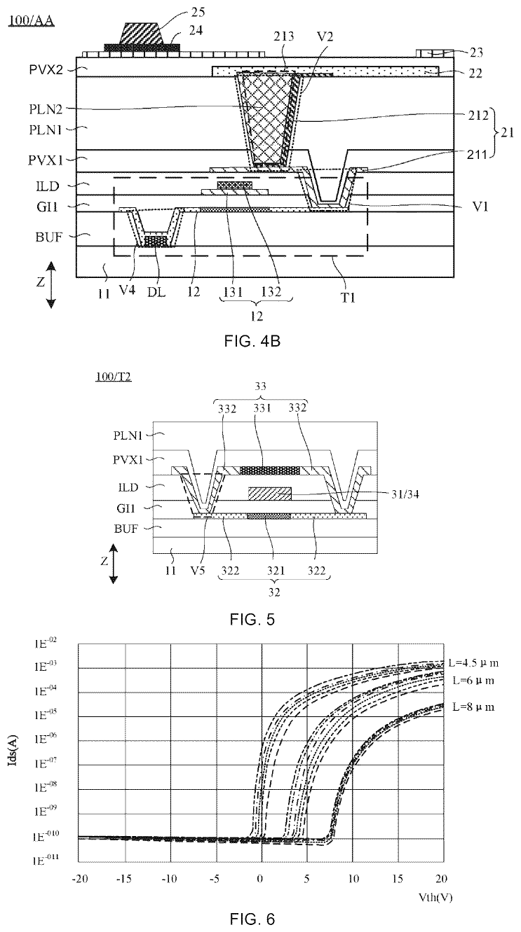

In some embodiments, referring to FIG. 5, the array substrate 100 also includes a second transistor T2. The second transistor T2 and the first transistor T1 are located on the same side of the base 11, and is disposed in the peripheral area BB, and exemplarily, the second transistor T2 may be a transistor configured to form a gate driving circuit or may be a transistor configured to form an MUX circuit, etc, and the embodiments of the present disclosure are not limited thereto, and the manufacturing and forming of any other circuit may be considered. Below, the embodiments of the present disclosure are described exemplarily by taking the second transistor T2 being configured to form the gate driving circuit as an example.

As shown in FIG. 5, the second transistor T2 includes a second semiconductor pattern 32 and a third semiconductor pattern 33. The third semiconductor pattern 33 may be located on a side of the second semiconductor pattern 32 away from the base 11. The second semiconductor pattern 32 includes a second channel area 321 and two second pole areas 322 located on two opposite sides of the second channel area 321. The third semiconductor pattern 33 includes a third channel area 331 and two third pole areas 332 located on two opposite sides of the third channel area 331.

The second channel area 321 and the third channel area 331 have an interval in a direction perpendicular to the base 11 (in a third direction Z), and in this way, conductive interfaces may be formed on the second channel area 321 and the third channel area 331 respectively, thereby improving the on-state current of the second transistor T2.

An orthographic projection of the second channel area 321 on the base 11 overlaps at least partially with an orthographic projection of the third channel area 331 on the base 11, which is not only conducive to reducing a size of an orthographic projection of the second transistor T2 on the base 11, i.e., reducing a size occupied by the second transistor T2 on the plane in which the array substrate 100 is located, thereby reducing the width of the peripheral area BB, conducive to achieving a narrow border for the array substrate 100 and the display apparatus, but also conducive to electrically connecting the second pole area 322 and the third pole area 332. Exemplarily, the second pole area 322 and the third pole area 332 located on the same side of the second channel area 321 and the third channel area 331 are electrically connected, to facilitate the synchronous transmission of electrical signals to the second pole area 322 and the third pole area 332.

The second transistor T2 provided in the embodiments of the present disclosure includes two semiconductor patterns (the second semiconductor pattern 32 and the third semiconductor pattern 33) arranged in a direction perpendicular to the base 11 (in a third direction Z), and in a case where the second transistor T2 is conductive, conductive interfaces may be formed on at least one surface of the two semiconductor patterns respectively, to form at least two conductive interfaces, which is conducive to improving the on-state current of the second transistor T2, and based on this, the second transistor with a smaller size may be designed, by reducing the width-to-length ratio of the second transistor T2 and decreasing the size of the second transistor T2, and which is conducive to simplifying the structure of the gate driving circuit, reducing a size of an orthographic projection of the gate driving circuit on the base 11, which is conducive to reducing the width of the peripheral area, to facilitate achieving a narrow border for the array substrate and the display apparatus.

In some embodiments, both the second semiconductor pattern 32 and the third semiconductor pattern 33 include a metal oxide semiconductor material. That is, the second transistor T2 may be a metal oxide thin-film transistor, which is conducive to reducing the manufacturing difficulty and manufacturing cost of the array substrate. Moreover, compared to the traditional metal oxide thin-film transistor that includes only one layer of semiconductor material, in the embodiments of the present disclosure, the second transistor T2 includes the second semiconductor pattern 32 and the third semiconductor pattern 33, which is conducive to improving the on-state current of the second transistor T.

The gate driving circuit typically includes multiple thin film transistors, and at least one of the multiple thin film transistors is the second transistor T2 described in the embodiments of the present disclosure.

The gate driving circuit typically includes multiple thin film transistors, and according to the functional and positional differences of the multiple thin film transistors, there are certain differences in the size (the width-to-length ratio of the channel structure) of the multiple thin film transistors. That is, among the multiple thin film transistors, the channel lengths of different thin film transistors are not exactly the same. The inventors have found that, the threshold voltage of the metal oxide thin-film transistor is certainly related to the channel length of the thin film transistor. For example, referring to FIG. 6, by detecting threshold voltages of metal oxide thin-film transistors with channel lengths of 4.5 μm, 6 μm, and 8 μm, respectively, it is found that: when the channel length of the metal oxide thin-film transistor is 4.5 μm, the threshold voltage Vth of the thin-film transistor is-1V to 0V approximately; when the channel length of the metal oxide thin-film transistor is 6 μm, the threshold voltage Vth of the thin-film transistor is 3V to 5V approximately; and when the channel length of the metal oxide thin-film transistor is 8 μm, the threshold voltage Vth of the thin-film transistor is 5V to 10V approximately. In this way, for metal oxide thin-film transistors with different sizes in the gate driving circuit, the required gate driving voltages may be different, which is not conducive to guaranteeing characteristics of the thin film transistors in the display area AA and the peripheral area BB to be homogeneous under the same manufacturing process, and thus is not conducive to the control and driving of the array substrate, for example the different transistor requires different gate voltages to drive.

The embodiments of the present disclosure provide an array substrate 100, the array substrate 100 includes two semiconductor patterns (the second semiconductor pattern 32 and the third semiconductor pattern), and in a case of the same channel width-to-length ratio, the on-state current of the second transistor T2 may be improved. Based on this, the second transistor T2 may have a greater process adjustment space, for example, the size of the transistor that had a large size originally may be reduced, which frees up the space in the peripheral area, or the size of the transistor that had a small size originally may also be increased, which is conducive to improving the uniformity of sizes among different thin film transistors, and conducive to solving the problem of threshold voltages of different thin film transistors being different.

In some embodiments, the electron mobility of the second semiconductor pattern 32 is greater than the electron mobility of the third semiconductor pattern 33, which is conducive to improving the on-state current of the second semiconductor pattern 32. Exemplarily, the second semiconductor pattern may include a high-mobility metal oxide semiconductor material, and the high-mobility metal oxide semiconductor material is referred to the above and will not be repeated here.

The electron mobility of the third semiconductor pattern 33 is less than or equal to the electron mobility of the second semiconductor pattern 32, but the light stability of the third semiconductor pattern 33 is greater than the light stability of the second semiconductor pattern 32. The third semiconductor pattern 33 is more susceptible to light including ambient light, therefore, using a material with stronger light stability for the third semiconductor pattern 33 is beneficial for improving the light stability of the second transistor T2. Exemplarily, the material of the third semiconductor pattern 33 includes indium gallium zinc oxide (IGZO), and the indium gallium zinc oxide (IGZO) has better light stability.

In the second semiconductor pattern 32, the second channel area 321 and the second pole area 322 are of one-piece structure, and the materials of the second channel area 321 and the second pole area 322 both include the same semiconductor material. The difference between the second pole area 322 and the second channel area 321 lies in that: the second pole area 322 undergoes a process that makes it more conductive (conductive process). The conductive process is referred to the above and will not be repeated here.

In the third semiconductor pattern 33, the third channel area 331 and the third pole area 332 are of one-piece structure, and the materials of the third channel area 331 and the third pole area 332 both include the same semiconductor material. The difference between the third channel area 331 and the third pole area 332 lies in that: the third pole area 332 undergoes a process that makes it more conductive (conductive process). The conductive process is referred to the above and will not be repeated here.

In some embodiments, the second transistor T2 also includes a second electrode structure 31, the second electrode structure 31 and the second channel area 321 are at least partially disposed opposite each other, and the second electrode structure 31 and the third channel area 331 are at least partially disposed opposite each other. The second electrode structure 31 is configured to control the second channel area 321 and the third channel area 331 to be conductive. The second electrode structure 31 is at least partially disposed opposite to the second channel area 321 and the third channel area 331 respectively, so that in a case where the second electrode structure 31 drives the second transistor T2 to be conductive, at least one conductive interface may be formed on the second channel area 321 and the third channel area 331 respectively, thereby obtaining at least two conductive interfaces, and improving the on-state current of the second transistor T2.

In some embodiments, referring to FIG. 5, the second electrode structure 31 may include a first sub-electrode 34 disposed between the second semiconductor pattern 32 and the third semiconductor pattern 33, the first sub-electrode 34 is disposed opposite to the second channel area 321 and the third channel area 331 respectively, and the first sub-electrode 34 may simultaneously control the second channel area 321 and the third channel area 331 to be turned on or turned off.

For example, when the working voltage (a voltage that can drive the second channel area 321 and the third channel area 331 to be conductive) is transmitted on the first sub-electrode 34, a current conductive interface is formed on a surface (top surface) of the second channel area 321 near the first sub-electrode 34, a current conductive interface is formed on a surface (bottom surface) of the third channel area 331 near the first sub-electrode 34, and both the second channel area 321 and the third channel area 331 achieve to be conductive, which is conducive to simplifying the structure of the second electrode structure 31.

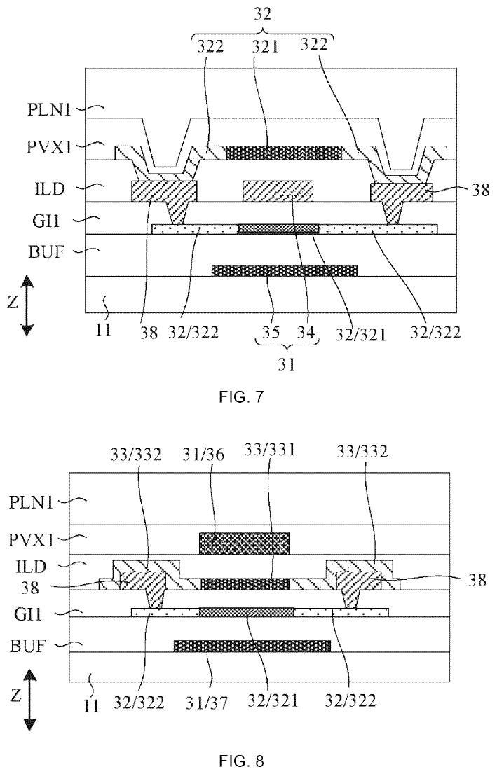

In some other embodiments, referring to FIG. 7, the second electrode structure 31 may include a first sub-electrode 34 disposed between the second semiconductor pattern 32 and the third semiconductor pattern 33, and a second sub-electrode 35 disposed on a side of the second semiconductor pattern 32 near the base 11.

In this way, in a case where the first sub-electrode 34 and the second sub-electrode 35 control the second channel area 321 and the third channel area 331 to be conductive, the second channel area 321 and the third channel area 331 may form three current conductive interfaces, which further increases the on-state current of the second transistor T2, which is conducive to further reducing the size of the second transistor T2, thereby reducing the space occupied by the gate driving circuit and reducing the width of the peripheral area, which helps the array substrate 100 and the display apparatus to achieve a narrow border.

Continuing to refer to FIG. 7, the first sub-electrode 34 is disposed opposite to the second channel area 321 and the third channel area 331 respectively, the first sub-electrode 34 may simultaneously control the second channel area 321 and the third channel area 331 to be turned on or turned off. Exemplarily, when the working voltage is transmitted on the first sub-electrode 34, a surface (top surface) of the second channel area 321 near the first sub-electrode 34 and a surface (bottom surface) of the third channel area 331 near the first sub-electrode 34 form a conductive interface respectively, and both the second channel area 321 and the third channel area 331 achieve to be conductive.

The second sub-electrode 35 is disposed opposite to the second channel area 321, and an orthographic projection of the second sub-electrode 35 on the base 11 overlaps at least partially with an orthographic projection of the second channel area 321 on the base 11. In this way, the second sub-electrode 35 may be configured to control the second channel area 321 to be turned on or turned off. Exemplarily, when the working voltage (a voltage that can drive the second channel area 321 to be conductive) is transmitted on the second sub-electrode 35, a surface of the second channel area 321 near the second sub-electrode 35 (bottom surface) forms a current conductive interface, and the second channel area 321 achieves to be conductive.

In a case where the second electrode structure 31 drives the second transistor T2 to be conductive, as shown in FIG. 7, the first sub-electrode 34 and the second sub-electrode 35 simultaneously transmit the working voltage, current conductive interfaces are formed on a top surface and a bottom surface of the second channel area 321 respectively, and a current conductive interface is formed on a bottom surface of the third channel area 331, so the second transistor T2 may form three current conductive interfaces in total. Under the same width-to-length ratio, the on-state current of the second transistor T2 may improve by nearly three times, which is conducive to reducing the size of the second transistor T2, decreasing the space occupied by the gate driving circuit, and enabling the array substrate and the display apparatus to achieve a narrow border.

It should be noted that, as shown in FIG. 7, in a case where the second electrode structure 31 includes the first sub-electrode 34 and the second sub-electrode 35, the second sub-electrode 35 may also not transmit a voltage signal, in which case the second sub-electrode 35 may be in a floating state, that is, the second sub-electrode 35 is not electrically connected to any other signal line, and the second sub-electrode 35 is only used to light-shielding the second channel area 321.

In some embodiments, referring to FIG. 7, an orthographic projection of the second sub-electrode 35 on the base 11 covers orthographic projections of the second channel area 321 and the third channel area 331 on the base 11, and partially overlaps with an orthographic projection of at least one of the two second pole areas 322 and the two third pole areas 332 on the base 11; in this way, the second sub-electrode 35 may also significantly shield the light emitted from the backlight source to the array substrate, which reduces the risk of the aforementioned light being emitted into the second channel area 321 and the third channel area 331, and then reduces the risk of a characteristic shift (such as Vth drift) of the second channel area 321 and the third channel area 331 under an illumination condition, which is conducive to improving the stability of the second channel area 321 and the third channel area 331, and then improving the stability of the second transistor T2.

An orthographic projection of the second sub-electrode 35 on the base 11 also covers an orthographic projection of the first sub-electrode 34 on the base 11, and a boundary of the orthographic projection of the second sub-electrode 35 has an interval with a boundary of the orthographic projection of the first sub-electrode 34. Thus, the light-shielding effect of the second sub-electrode 35 on the second channel area 321 and the third channel area 331 may be significantly improved.

Exemplarily, an orthographic projection of the second channel area 321 on the base 11 is within a range of an orthographic projection of the first sub-electrode 34 on the base 11, or in other words, in the procedure of the manufacturing and forming of the second semiconductor pattern 32, the second semiconductor pattern 32 may be made conductive by using the first sub-electrode 34 as a mask, to form the second channel area 321 and the second pole area 322 on the second semiconductor pattern 32. The second sub-electrode 35 covering the first sub-electrode 34 may ensure that the second sub-electrode 35 completely covers the second channel area 321.

In some embodiments, referring to FIG. 8, the second electrode structure 31 includes a third sub-electrode 36 disposed on a side of a third semiconductor pattern 33 away from the base 11, and a fourth sub-electrode 37 disposed on a side of the second semiconductor pattern 32 near the base 11. The third sub-electrode 36 is disposed opposite to the third semiconductor pattern 33, and an orthographic projection of the third sub-electrode 36 on the base 11 overlaps at least partially with an orthographic projection of the third channel area 331 on the base 11. The third sub-electrode 36 is configured to drive the third channel area 331 of the third semiconductor pattern 33 to be turned on and turned off. The fourth sub-electrode 37 is disposed opposite to the second semiconductor pattern 32, and an orthographic projection of the fourth sub-electrode 37 on the base 11 overlaps at least partially with an orthographic projection of the second channel area 321 on the base 11. The fourth sub-electrode 37 is configured to drive the second channel area 321 of the second semiconductor pattern 32 to be turned on and turned off.

Exemplarily, in a case where the second electrode structure 31 drives the second channel area 321 and the third channel area 331 of the second transistor T2 to be conductive, a first working voltage (a voltage that can drive the third channel area 331 to be conductive) is transmitted on the third sub-electrode 36, and under the control of the first working voltage, a current conductive interface is formed on a surface (top surface) of the third channel area 331 near the third sub-electrode 36; and at the same time, a second working voltage (a voltage that can drive the second channel area 321 to be conductive) is transmitted on the fourth sub-electrode 37, and under the control of the second working voltage, a current conductive interface is formed on a surface (bottom surface) of the second channel area 321 near the fourth sub-electrode 37. That is, the third sub-electrode 36 and the fourth sub-electrode 37 drive the third channel area 331 and the second channel area 321 to be conductive respectively, and form a current conductive interface respectively, in which case the second transistor T2 includes two current conductive interfaces.

In some embodiments, referring to FIG. 8, in a case where the second electrode structure 31 includes the third sub-electrode 36 and the fourth sub-electrode 37, the fourth sub-electrode 37 may also be used to shield the light emitted from the backlight source to the array substrate, which reduces the risk of the aforementioned light being emitted into the second channel area 321 and the third channel area 331, and then reduces the risk of a characteristic shift (such as Vth drift) of the second channel area 321 and the third channel area 331 under an illumination condition, which is conducive to improving the stability of the second channel area 321 and the third channel area 331, and then improving the stability of the second transistor T2.

Exemplarily, an orthographic projection of the fourth sub-electrode 37 on the base 11 covers orthographic projections of the second channel area 321 and the third channel area 331 on the base 11, and partially overlaps with an orthographic projection of at least one of the two second pole areas 322 and the two third pole areas 332 on the base 11. In this way, the light-shielding effect of the second sub-electrode 35 on the second channel area 321 and the third channel area 331 may be significantly improved, thereby improving the stability of the second transistor T2.

Obviously, the specific structure of the second electrode structure 31 is not limited to the multiple embodiments described above (the embodiments in FIG. 5 to FIG. 8), as long as the second electrode structure 31 uses the same technical idea as the present application. For example, the second electrode structure may include a first sub-electrode located between the second semiconductor pattern and the third semiconductor pattern, a second sub-electrode located a side of the second semiconductor pattern near the base, and a third sub-electrode located a side of the third semiconductor pattern away from the base (not shown in the figure). Alternatively, the second electrode structure may include a first sub-electrode located between the second semiconductor pattern and the third semiconductor pattern, and a third sub-electrode located a side of the third semiconductor pattern away from the base (not shown in the figure). The second electrode structure of the embodiments of the present disclosure is not limited thereto, and will not be listed one by one here.

In some embodiments, referring to FIG. 5, FIG. 7 and FIG. 8, at least one insulating layer is included between the second semiconductor pattern 32 and the third semiconductor pattern 33.

Referring to FIG. 5, the first insulating layer GI1 and the second insulating layer ILD are included between the second semiconductor pattern 32 and the third semiconductor pattern 33. The array substrate 100 may also include a fifth via-hole V5, and the fifth via-hole V5 passes through the insulating layers (the first insulating layer GI1 and the second insulating layer ILD) between the second semiconductor pattern 32 and the third semiconductor pattern 33, and exposes at least a part of the second pole area 322. The second pole area 322 of the second semiconductor pattern 32 and the third pole area 332 and the third semiconductor pattern 33 that are close to each other may be directly electrically connected with each other through the fifth via-hole V5.

Alternatively, in some embodiments, referring to FIG. 7 and FIG. 8, the second transistor T2 also includes at least one adaptor pattern 38, and the adaptor pattern 38 is disposed between the second pole area 322 and the third pole area 332 that are close to each other, and is electrically connected to the second pole area 322 and the third pole area 332 respectively. In this way, it is conducive to reducing the depth of the connection via-hole between the second pole area 322 and the third pole area 332, reducing the difficulty of connecting the second pole area 322 and the third pole area 332, and conducive to improving the conductivity effect of the third pole area 332. Exemplarily, the second transistor T2 includes two adaptor patterns 38, and the two adaptor patterns 38 are respectively disposed between two pairs of the second pole area 322 and the third pole area 332 that are connected with each other.

Referring to FIG. 7, in a case where the second transistor T2 includes the adaptor pattern 38 and the second electrode structure 31 includes the first sub-electrode 34, the adaptor pattern 38 may include the same material and be disposed on the same layer as the first sub-electrode 34. Exemplarily, the adaptor pattern 38 is formed in the same patterning process by using the same mask and/or using the same material as the first sub-electrode 34. In this way, it is conducive to simplifying the manufacturing process for the adaptor pattern 38 and the first sub-electrode 34, and reducing the manufacturing cost of the array substrate.

Referring to FIG. 8, in a case where the second electrode structure 31 includes the third sub-electrode 36 and the fourth sub-electrode 37, but does not include the first sub-electrode 34, the adaptor pattern 38 may be disposed separately on a film layer, and the third semiconductor pattern 33 may be disposed on the adaptor pattern 38 (as shown in FIG. 8). Alternatively, at least one insulating layer may be disposed between the adaptor pattern 38 and the third semiconductor pattern 33, and a via-hole may be disposed on the insulating layer, and the adaptor pattern 38 and the third semiconductor pattern 33 are connected through the via-hole (not shown in the figure).

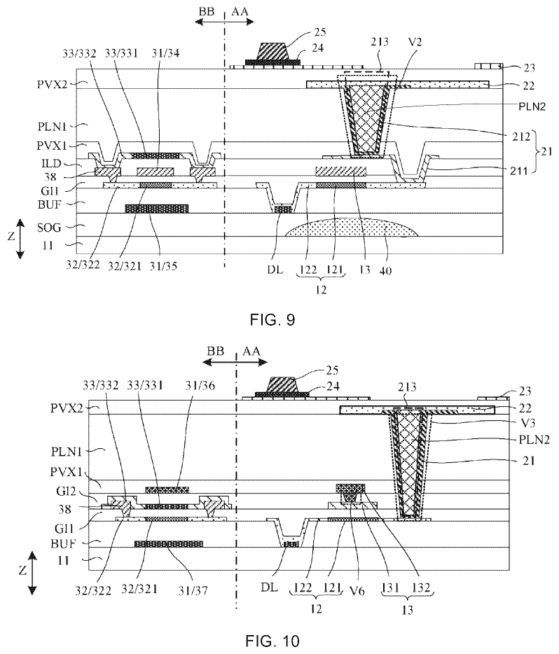

In some embodiments, referring to FIG. 9, the second semiconductor pattern 32 includes the same material and is disposed in the same layer as the first semiconductor pattern 12. And/or, referring to FIG. 9 and FIG. 10, the third semiconductor pattern 33 includes the same material and is disposed in the same layer as one of the connecting electrode 21 and the first electrode structure 13 which includes a semiconductor material. Compared with using different processes, and manufacturing and forming the first semiconductor pattern 12, the second semiconductor pattern 32, the third semiconductor pattern 33, the connecting electrode 21, and the first electrode structure 13 on different film layers respectively, the second semiconductor pattern 32 includes the same material and is disposed in the same layer as the first semiconductor pattern 12, and the third semiconductor pattern 33 includes the same material and is disposed in the same layer as one of the connecting electrode 21 and the first electrode structure 13 which includes a semiconductor material, which may significantly simplify the manufacturing process of the array substrate 100 and simplify the structure of the array substrate 100, which is conducive to reducing the manufacturing cost of the array substrate 100.

Exemplarily, referring to FIG. 9 and FIG. 10, the second semiconductor pattern 32 is formed in the same patterning process by using the same mask and/or using the same material as the first semiconductor pattern 12. Referring to FIG. 9, in a case where the connecting electrode 21 includes a semiconductor material, the third semiconductor pattern 33 may be formed in the same patterning process by using the same mask and/or using the same material as the connecting electrode 21. Alternatively, referring to FIG. 10, in a case where the first electrode structure 13 includes a semiconductor material, the third semiconductor pattern 33 may be formed in the same patterning process by using the same mask and/or using the same material as the first electrode structure 13. In a case where both the connecting electrode 21 and the first electrode structure 13 include a semiconductor material, the third semiconductor pattern 33 may be formed in the same patterning process by using the same mask and/or using the same material as any one of the connecting electrode 21 and the first electrode structure 13.

In some embodiments, referring to FIG. 9, the connecting electrode 21 includes a semiconductor material, and the third semiconductor pattern 33 includes the same material and is disposed in the same layer as the connecting electrode 21. Exemplarily, the connecting electrode 21 is formed in the same patterning process by using the same mask and/or using the same material as the third semiconductor pattern 33. In this way, it is conducive to simplifying the manufacturing process of the third semiconductor pattern 33, and reducing the manufacturing cost of the array substrate.

Continuing to refer to FIG. 9, the connecting electrode 21 includes a first sub-connecting electrode 211 and a second sub-connecting electrode 212, and the second sub-connecting electrode 212 is located on a side of the first sub-connecting electrode 211 away from the base 11; that is, the first pole area 122 of the first semiconductor pattern 12 is electrically connected to the first electrode 22 through the first sub-connecting electrode 211 and the second sub-connecting electrode 212 in sequence.

As shown in FIG. 9, the third semiconductor pattern 33 includes the same material and is disposed in the same layer as the first sub-connecting electrode 211. In this way, it is conducive to decreasing the interval between the third semiconductor pattern 33 and the second semiconductor pattern 32 in the third direction Z, and reducing the connection difficulty between the second pole area 322 and the third pole area 332.

Continuing to refer to FIG. 9, the array substrate 100 may also include a first planar layer PLN1, a second planar layer PLN2, and a second via-hole V2. The first planar layer PLN1 is disposed between the first sub-connecting electrode 211 and the second sub-connecting electrode 212, and exemplarily, a third insulating layer PVX1 is also included between the first planar layer PLN1 and the first sub-connecting electrode 211.

The first sub-connecting electrode 211 may include a first portion and a second portion, the first portion passes through the first via-hole V1 and then is electrically connected to the first semiconductor pattern 12, and the second portion is located on a surface of the second insulating layer ILD away from the base 11.

The second via-hole V2 passes through the first planar layer PLN1 and the third insulating layer PVX1, and exposes at least a part of the second portion of the first sub-connecting electrode 211. The second sub-connecting electrode 212 passes through the second via-hole V2 and then is connected to the second portion, and a part of the second sub-connecting electrode 212 located within the second via-hole V2 includes a slot 213 recessed towards a side close to the base 11. The second planar layer PLN2 is disposed between the second sub-connecting electrode and the first electrode and located within the second via-hole V2, and is disposed within the slot 213. A surface of the second planar layer PLN2 away from the base 11 is roughly flush with a surface of the second sub-connecting electrode 212 away from the base 11, to improve the flatness of a plane in which the first electrode 22 is located, and improve the flatness of the first electrode 22, which is conducive to improving the uniformity of the electric field formed between the first electrode 22 and the second electrode 23.

It should be noted that the above “a surface of the second planar layer PLN2 away from the base 11 is roughly flush with a surface of the second sub-connecting electrode 212 away from the base 11” may mean that, for example, a step between the surface of the second planar layer PLN2 away from the base 11 and the surface of the second sub-connecting electrode 212 away from the base 11 is less than a first threshold, and the first threshold may be, for example, 2 μm, 3 μm, 3.5 μm, or 5 μm, etc., which will not be listed one by one in the embodiments of the present disclosure. In this way, on the one hand, it may effectively improve the flatness of the surface of the array substrate, and then improve the uniformity of the box thickness of the liquid crystal layer; on the other hand, it may reduce the problem of the light leakage at the second via-hole V2.

In some embodiments, an orthographic projection of the second via-hole V2 on the base 11 is located within an orthographic projection of the pixel area 101 on the base 11. Specifically, the size of the orthographic projection of the pixel area 101 on the base 11 is larger than the size of the orthographic projection of the second via-hole V2 on the base 11, the orthographic projection of the pixel area 101 on the base 11 covers the orthographic projection of the second via-hole V2 on the base 11, so that the first electrode 22 is electrically connected to the first semiconductor pattern 12 through the second via-hole V2.

In the embodiments of the present disclosure, compared to disposing the second via-hole V2 in a non-pixel area (such as a position in which the first signal line DL or the second signal line GL is located), which would result in the part of the first electrode 22 located within the second via-hole V2 being used only for the electrical connection with the first semiconductor pattern (the connecting electrode 21) but not for displaying, causing the smaller effective size of the first electrode 22, while in the embodiments of the present disclosure, the second via-hole V2 that electrically connects the first electrode 22 and the first semiconductor pattern 12 is disposed in the pixel area 101, the part of the first electrode 22 located within the second via-hole V2 may also generate an electric field with the second electrode 23, and the part may also be used for displaying, which can increase the effective size of the first electrode 22, improve the liquid crystal efficiency (the ability of the liquid crystal to deflect the linear polarization light), and is conducive to improving the light transmittance of the display panel.

In the embodiments of the present disclosure, the connecting electrode 21 includes a first sub-connecting electrode 211 and a second sub-connecting electrode 212, and the first sub-connecting electrode 211 is electrically connected to the first semiconductor pattern 12 through the first via-hole V1, the second sub-connecting electrode 212 is electrically connected to the first sub-connecting electrode 211 through the second via-hole V2, an orthographic projection of the first via-hole V1 and an orthographic projection of the second via-hole V2 on the base 11 do not overlap (are misaligned) with each other, and the first via-hole V1 and the second via-hole V2 may be manufactured and formed by a two-step etch process respectively, which is compared to one passing via-hole, conducive to reducing the etch difficulty of the first via-hole V1 and the second via-hole V2, and conducive to improving the continuity of the first sub-connecting electrode 211 and the second sub-connecting electrode 212 within the first via-hole V1 and the second via-hole V2 respectively, thereby reducing the ramp-up difficulty of the first sub-connecting electrode 211 and the second sub-connecting electrode 212.

In some embodiments, the specific pattern of the second sub-connecting electrode 212 may be designed as needed, and the orthographic projection of the second sub-connecting electrode 212 on the base 11 may specifically be triangular, quadrilateral, pentagonal, hexagonal, circular, elliptical, or other irregular shapes. The specific pattern of the second sub-connecting electrode 212 needs to meet that: on the one hand, it may achieve a lap joint with the first electrode 22, and on the other hand, after the second sub-connecting electrode 212 is stacked with the first electrode 22, the overall outer contour of both covers the orthographic projections of the second via-hole V2 and the first via-hole V1 on the base 11.

In some embodiments, as shown in FIG. 4A, the second sub-connecting electrode 212 at the second via-hole V2 may only cover a side of the first planar layer PLN1 located on the second via-hole V2, that is, the second sub-connecting electrode 212 does not completely cover the sidewall of the second via-hole V2. In this case, as shown in FIG. 4A, the second sub-connecting electrode 212 at a hole bottom of the second via-hole V2 may cover the entire hole bottom of the second via-hole V2. Alternatively, it may cover a part of the entire hole bottom of the second via-hole V2 (not shown in the figure). Alternatively, as shown in FIG. 9, the second sub-connecting electrode 212 may also, at the second via-hole V2, cover the entire outer edge of the first planar layer PLN1 away from the base 11, that is, the second sub-connecting electrode 212 completely covers the sidewall of the second via-hole V2.

In some embodiments, an orthographic projection of the first electrode 22 on the base 11 covers orthographic projections of the second via-hole V2 and the first via-hole V1 on the base 11. Since the second sub-connecting electrode 212 is distributed within the second via-hole V2 and the first sub-connecting electrode 211 is distributed within the first via-hole V1, the connecting electrodes 21 within the holes may form an electric field with the second electrode 23 above the first electrode 22, which may interfere with the normal electric field formed by the first electrode 22 and the second electrode 23, thereby affecting the electric field loaded on the liquid crystal layer. In the embodiments of the present disclosure, by the first electrode 22 covering orthographic projections of the second via-hole V2 and the first via-hole V1 on the base 11, the electric field within the holes may be shielded, thereby achieving the effect of stabilizing the electric field.

In some embodiments, referring to FIG. 5, FIG. 7, and FIG. 8 simultaneously, in a case where the second electrode structure 31 includes the first sub-electrode 34, the first sub-electrode 34 may include the same material and be disposed in the same layer as the first electrode structure 13. Exemplarily, the first sub-electrode 34 is formed in the same patterning process by using the same mask and/or using the same material as the first electrode structure 13. In this way, the first sub-electrode 34 may be formed at the same time of the manufacturing of the first electrode structure 13, without the need for a separate process to manufacture the first sub-electrode 34, which may simplify the manufacturing process of the first sub-electrode 34, and reduce the manufacturing difficulty and manufacturing cost of the array substrate.

In some embodiments, as shown in FIG. 9, the first signal line DL is disposed on a side of the first semiconductor pattern 12 near the base 11. In a case where the second electrode structure 31 includes a second sub-electrode 35, the first signal line DL includes the same material and is disposed in the same layer as the second sub-electrode 35. Exemplarily, the second sub-electrode 35 is formed in the same patterning process by using the same mask and/or using the same material as the first signal line DL. In this way, the second sub-electrode 35 may be formed at the same time of the manufacturing of the first signal line DL, without the need for a separate process to manufacture the second sub-electrode 35, which may simplify the manufacturing process of the second sub-electrode 35, and reduce the manufacturing difficulty and manufacturing cost of the array substrate.

As shown in FIG. 9, the second transistor T2 includes a second electrode structure 31, a second semiconductor pattern 32, and a third semiconductor pattern 33, and the second electrode structure 31 includes a first sub-electrode 34 and a second sub-electrode 35. Along a direction away from the base 11, the second sub-electrode 35 may include the same material and be disposed in the same layer as the first signal line DL, the second semiconductor pattern 32 may include the same material and be disposed in the same layer as the first semiconductor pattern 12, the first sub-electrode 34 may include the same material and be disposed in the same layer as the first electrode structure 13, and the third semiconductor pattern 33 may include the same material and be disposed in the same layer as the first sub-connecting electrode 212. Based on this, the structure of the second transistor T2 may be formed synchronously with the film layer of the display area, and without increasing the manufacturing step of the array substrate 100, the second transistor T2 may be provided as a thin film transistor including two semiconductor patterns, which may increase the on-state current of the second transistor T2, reduce the size of the second transistor T2, minimize the space occupied by the gate driving circuit, and enable the array substrate and the display apparatus to achieve a narrow border, in a case where the existing process condition and manufacturing procedure are unchanged.

It can be understood that the above FIG. 9 is only a specific embodiment, and any of at least one structure or film layer of the second transistor T2 may be also manufactured and formed by using a separate process, as long as the structure of the second transistor T2 uses the same technical idea.

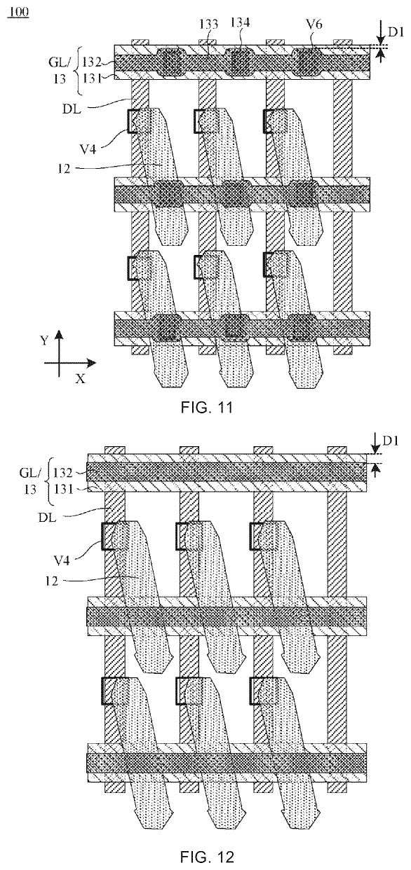

In some embodiments, referring to FIG. 10 and FIG. 11, the first electrode structure 13 includes an auxiliary electrode 131 and an electrode portion 132, the electrode portion 132 is located on a side of the auxiliary electrode 131 away from the base 11, and the material of the auxiliary electrode 131 includes a semiconductor material.

Here, the third semiconductor pattern 33 includes the same material and is disposed in the same layer as the auxiliary electrode 131. Exemplarily, the third semiconductor pattern 33 is formed in the same patterning process by using the same mask and/or using the same material as the auxiliary electrode 131. In this way, it is conducive to simplifying the manufacturing process of the third semiconductor pattern 33 and reducing the manufacturing cost of the array substrate.

Here, the material of the auxiliary electrode 131 may include a transparent conductive material, to improve the transmittance of a part of the auxiliary electrode 131 that extends out of the electrode portion 132, thereby reducing the shielding of light from the pixel area 101 by the aforementioned part. Exemplarily, the transparent conductive material includes but is not limited to: metal oxide (such as at least one of indium tin oxide, indium gallium zinc oxide, indium-doped zinc oxide (AZO), fluorine-doped tin oxide (AZO), aluminum-doped zinc oxide (AZO), indium-doped cadmium oxide).

In some embodiments, as shown in FIG. 11, an orthographic projection of the auxiliary electrode 131 on the base 11 covers an orthographic projection of the electrode portion 132 on the base 11, and the auxiliary electrode 131 is configured to increase the size of the first channel area 121 in the first semiconductor pattern 12, to improve the width-to-length ratio of the first transistor T1, and improve the on-state current of the first transistor T1.

Specifically, for the array substrate with the ultra-high resolution, the aperture ratio of the pixel area may be increased directly and efficiently by optimizing the line width of the traces (the first signal line and the second signal line) and the size of the via-holes, thereby optimizing the displaying effect. However, at the same time, the effect of the channel length being reduced also poses a corresponding challenge to the short-channel characteristic of the transistor in the display backboard. When the channel length is less than 2 μm, the obvious short-channel effect will appear in the oxide transistor, where the effect mainly includes the drain induced barrier lowering (Drain Induced Barrier Lowering, DIBL) effect and the conductive doped diffusion effect, both of which impact the characteristic of the oxide transistor, so that the characteristic cannot be ensured. In the embodiments of the present disclosure, the first electrode structure 13 also includes the auxiliary electrode 131, and under the premise of the line width of the electrode portion 132 being reduced, on the one hand, the injection of some ions may be blocked when making the first semiconductor pattern 12 conductive subsequently, and the channel length is extended, which can ensure the characteristic of the oxide transistor, and avoid the drain induced barrier lowering effect and the conductive doped diffusion effect, and on the other hand, the transparent auxiliary electrode 131 does not affect the transmittance of the light transmission area.

Exemplarily, an orthographic projection of the auxiliary electrode 131 on the base 11 covers an orthographic projection of the electrode portion 132 on the base 11, and covers at least one side of two sides of the electrode portion 132 in the second direction Y. For example, as shown in FIG. 11 and FIG. 12, an orthographic projection of the auxiliary electrode 131 on the base 11 covers an orthographic projection of the electrode portion 132 on the base 11, and covers two sides of the electrode portion 132 in the second direction Y.

In the embodiments of the present disclosure, as shown in FIG. 10, in order to facilitate the disposing of the third semiconductor pattern 33 and the third sub-electrode 36, a third insulating layer GI2 is disposed between the auxiliary electrode 131 and the electrode portion 132. However, it should be understood that in some other embodiments, the auxiliary electrode 131 and the electrode portion 132 may contact with each other directly (as shown in FIG. 4B), and positions of the auxiliary electrode 131 and the electrode portion 132 in the third direction are interchangeable. The embodiments of the present disclosure are described exemplarily below, by taking an example in which the third insulating layer GI2 is disposed between the auxiliary electrode 131 and the electrode portion 132, and the auxiliary electrode 131 is located on a side of the electrode portion 132 near the base 11.

In some embodiments, the third sub-electrode 36 includes the same material and is disposed in the same layer as the electrode portion 132. Exemplarily, the third sub-electrode 36 is formed in the same patterning process by using the same mask and/or using the same material as the electrode portion 132. In this way, it is conducive to simplifying the manufacturing process of the third semiconductor pattern 33, and reducing the manufacturing cost of the array substrate.

In some embodiments, referring to FIG. 10, in a case where the first electrode structure 13 includes the auxiliary electrode 131 and the electrode portion 132, the array substrate 100 also includes the first insulating layer GI1, the third insulating layer GI2, the second insulating layer ILD, the first planar layer PLN1, the second planar layer PLN2 and the third via-hole V3.

Here, the first insulating layer GI1 is disposed between the first semiconductor pattern 12 and the first electrode structure 13. The third insulating layer GI2 is disposed between the auxiliary electrode 131 and the electrode portion 132. The second insulating layer ILD and the first planar layer PLN1 are disposed between the first electrode structure 13 (the electrode portion 132) and the connecting electrode 21, and the first planar layer PLN1 is located away from the base 11, compared to the second insulating layer ILD, or in other words, the first planar layer PLN1 is located on a side of the second insulating layer ILD away from the base 11.

The third via-hole V3 passes through the first planar layer PLN1, the second insulating layer ILD, the third insulating layer GI2 and the first insulating layer GI1, and exposes a part area of the first semiconductor pattern 12, such as a part area of a first pole area 122 of the first semiconductor pattern 12.

The connecting electrode 21 includes a third portion and a fourth portion, the third portion passes through the third via-hole V3 and then is electrically connected to the first semiconductor pattern 12, and the fourth portion is located on a surface of the first planar layer PLN1 away from the base 11 and is electrically connected to the first electrode 21. The third portion includes a slot 213 recessed towards the direction near the base 11, and the second planar layer PLN2 is disposed between the second sub-connecting electrode and the first electrode and located within the second via-hole V2, and disposed within the slot 213. A surface of the second planar layer PLN2 away from the base 11 is roughly flush with a surface of the second sub-connecting electrode 212 away from the base 11 (a step between the two surfaces is less than a first threshold), which improves the flatness of the plane in which the first electrode 22 is located, improves the flatness of the first electrode 22, and which is conducive to improving the uniformity of the electric field formed between the first electrode 22 and the second electrode 23. In addition, the flatness of the surface of the array substrate may also be improved effectively, thereby improving the uniformity of the box thickness of the liquid crystal layer; and it is conducive to reducing the problem of the light leakage at the second via-hole V2.

In some embodiments, referring to FIG. 10, the third via-hole V3 passes through the first planar layer PLN1, the second insulating layer ILD, the third insulating layer GI2, and the first insulating layer GI1, and may be etched by using a one-step etch method to form the third via-hole V3, and the connecting electrode 21 includes only one conductive layer, which is conducive to reducing one mask step, simplifying the manufacturing process of the array substrate, and reducing the manufacturing cost of the array substrate.

In some embodiments, continuing to refer to FIG. 10, the first signal line DL is disposed on a side of the first semiconductor pattern 12 near the base 11. In a case where the second electrode structure 31 includes a third sub-electrode 36 and a fourth sub-electrode 37, the first signal line DL includes the same material and is disposed in the same layer as the fourth sub-electrode 37. Exemplarily, the fourth sub-electrode 37 is formed in the same patterning process by using the same mask and/or using the same material as the first signal line DL. In this way, the fourth sub-electrode 37 may be formed at the same time of the manufacturing of the first signal line DL, without the need for a separate process to manufacture the fourth sub-electrode 37, which may simplify the manufacturing process of the fourth sub-electrode 37, and reduces the manufacturing difficulty and manufacturing cost of the array substrate.

In some embodiments, the auxiliary electrode 131 and the electrode portion 132 are both configured to drive the first transistor T1 to be turned on or turned off, and the auxiliary electrode 131 and the electrode portion 132 may transmit the same voltage signal. Exemplarily, the auxiliary electrode 131 and the electrode portion 132 are electrically connected.

In some embodiments, as shown in FIG. 10 and FIG. 11, the auxiliary electrode 131 and the electrode portion 132 are electrically connected within the display area AA. At this time, the third insulating layer GI2 includes a sixth via-hole V6, and the electrode portion 132 includes a main body portion 133 and a widened portion 134 that are connected alternately along the first direction X. An orthographic projection of the widened portion 134 on the base 11 overlaps at least partially with the sixth via-hole V6, and the widened portion 134 is electrically connected to the auxiliary electrode through the sixth via-hole.

In some embodiments, as shown in FIG. 11, there is a first interval D1 between a boundary of an orthographic projection of the auxiliary electrode 131 and a boundary of an orthographic projection of the electrode portion 132 on the base 11 that are close to each other, and the first interval D1 is greater than or equal to 0.5 μm. Exemplarily, in a case where the electrode portion 132 includes the main body portion 133 and the widened portion 134, the first interval D1 may refer to: an interval between a boundary of an orthographic projection of the auxiliary electrode 131 and a boundary of an orthographic projection of the widened portion 134 on the base 11 that are close to each other.

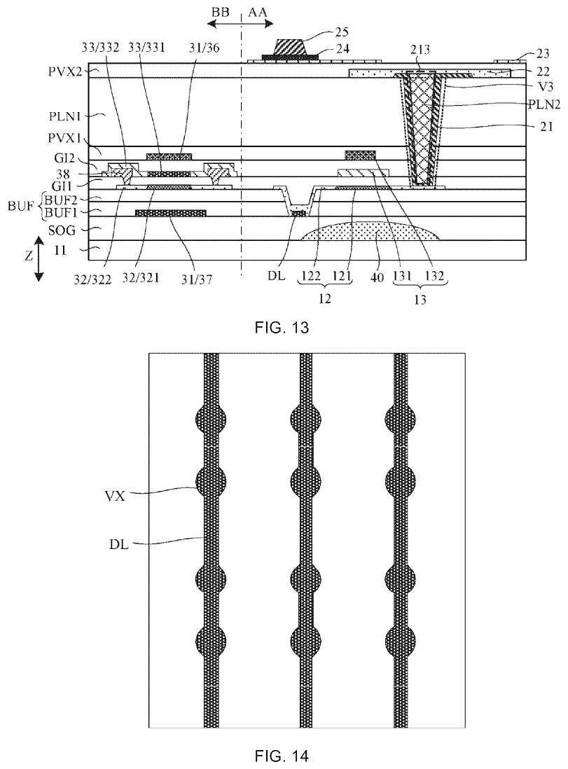

In some other embodiments, referring to FIG. 12 and FIG. 13, the auxiliary electrode 131 and the electrode portion 132 are electrically connected within the peripheral area. At this time, the connection between the auxiliary electrode 131 and the electrode portion 132 within the display area AA is not through via-holes, and the width (the size along the second direction) of the electrode portion 132 in its extending direction (the first direction X) is uniform.

FIG. 14 is a structure diagram of the first signal line DL in a case where the first signal line DL is disposed on a side of the first semiconductor pattern 12 away from the base 11. Referring to FIG. 14, the applicants found that, in a case where the first signal line DL is disposed on a side of the first semiconductor pattern 12 away from the base 11, and for example, if the first signal line DL includes the same material and is disposed in the same layer as the first connecting sub-electrode, the first signal line DL is electrically connected to the first semiconductor pattern 12 through a connecting via-hole VX disposed between the first signal line DL and the first semiconductor pattern 12, the opening of the connecting via-hole VX is typically greater than the line width of the first signal line DL, a width of a part of the first signal line DL located within the connecting via-hole VX is greater than that of other parts, and an edge of the part within the connecting via-hole VX forms an angle with the extending direction of the first signal line DL, that is, the shape and the size of the first signal line DL at the connecting via-hole VX may differ from other positions (graphic distortion), and accordingly, when the polarized light shines on the part of the first signal line located at the connecting via-hole VX, the polarized light may undergo a phenomenon of metal diffraction depolarization, thereby leading to the light leakage problem at the connecting via-hole VX. To shield the connecting via-hole VX, a larger black matrix needs to be disposed, which is not conducive to improving the aperture ratio of the array substrate, and results in the light extraction efficiency of the array substrate being reduced.

To solve the aforementioned problems, in some embodiments of the present disclosure, referring to FIG. 9, FIG. 10, and FIG. 13, the first signal line DL is disposed within the display area AA, and disposed on a side of the first semiconductor pattern 12 near the base 11. The array substrate 100 may also include a buffer layer BUF and a fourth via-hole V4, and the buffer layer BUF is disposed between the first semiconductor pattern 12 and the first signal line DL. The fourth via-hole V4 passes through the buffer layer BUF and exposes a part area of the first signal line DL, the part of the first semiconductor pattern 12 is located within the fourth via-hole V4 and electrically connected to the first signal line DL through the fourth via-hole V4. In this way, the first signal line DL may be disposed on a relatively flat surface, without the need for a connecting via-hole disposed below the first signal line DL, and the shape and size of the first signal line DL is more uniform, which is conducive to reducing the size of the black matrix that shields the first signal line DL, and also conducive to the fine-line design of the first signal line DL, conducive to improving the aperture ratio of the array substrate, and improving the transmittance of the array substrate 100.

In addition, continuing to refer to FIG. 9, FIG. 10, and FIG. 13, the first signal line DL is disposed on a side of the first semiconductor pattern 12 near the base 11, so that the first signal line DL and the connecting electrode 21 may be located on two sides of the first semiconductor pattern 12 in the third direction Z respectively, thereby reducing the parasitic capacitance between the first signal line DL and the connecting electrode 21, which is conducive to reducing the impact of the voltage fluctuation of the first signal line DL on the connecting electrode 21 and the first electrode 22.

In some embodiments, referring to FIG. 12 and FIG. 13, the fourth via-hole V4 may expose two sidewalls of the first signal line DL that are opposite to each other, or in other words, along a direction perpendicular to the extending direction of the first signal line DL (along the first direction X), the size of the fourth via-hole V4 is larger than the size of the first signal line DL, and both ends of the fourth via-hole V4 extend out of the first signal line DL. Thus, the area of the first signal line DL that is exposed by the fourth via-hole V4 may be significantly increased. An orthographic projection of the first semiconductor pattern 12 on the base 11 covers at least a half of an orthographic projection of the fourth via-hole V4 on the base 11, and in this way, it may be ensured that the first semiconductor pattern 12 sufficiently contacts with the first signal line DL, which is conducive to increasing the contacting area between the first signal line DL and the first semiconductor pattern 12, increasing the reliability of the connection between the first signal line DL and the first semiconductor pattern 12, and conducive to reducing the contacting resistance between the first signal line DL and the first semiconductor pattern 12.

Exemplarily, the first semiconductor pattern 12 may completely cover the fourth via-hole V4, which may greatly increase the contacting area between the first semiconductor pattern 12 and the first signal line DL, and reduce the contacting resistance between the first semiconductor pattern 12 and the first signal line DL.

In addition, in some embodiments, referring to FIG. 13, the buffer layer BUF includes a first sub-layer BUF1 and a second sub-layer BUF2 stacked along a direction away from the base 11. The material of the first sub-layer BUF1 includes silicon nitride SiNx (x>0), and the material of the second sub-layer BUF2 includes silicon oxide SiOy (y>0). The first sub-layer BUF1 is directly contact with the first signal line DL, which is conducive to reducing the oxygen content in the first sub-layer BUF1, and exemplarily, the material of the first sub-layer BUF1 does not include oxygen. Based on this, in the subsequent process of manufacturing the first semiconductor pattern 12 (in a high-temperature environment), the risk of oxidation of the first signal line DL may be reduced, thereby improving the stability and reliability of the first signal line DL.

In some embodiments, along a direction perpendicular to the base 11 (the third direction Z), the thickness of the first sub-layer BUF1 is greater than or equal to 50 nm. Exemplarily, a range of the thickness of the first sub-layer BUF1 may be 50 μm to 200 μm (including endpoint values), or a range of the thickness of the first sub-layer BUF1 may be 200 μm to 500 μm (including endpoint values), etc., which will not be listed one by one in the embodiments of the present disclosure. For example, the thickness of the first sub-layer BUF1 may be 50 μm, 80 μm, 100 μm, 150 μm, or 300 μm, etc., which will not be listed one by one here.

In some embodiments, along a direction perpendicular to the base 11 (the third direction Z), the thickness of the first insulating layer GI is 80 nm to 150 nm. In this way, in the manufacturing process of the array substrate, and in the annealing process, the first insulating layer GI may provide good protection for the connected position between the first signal line DL and the first semiconductor pattern 12, which can reduce the contacting resistance between the first signal line DL and the first semiconductor pattern 12. Exemplarily, the thickness of the first insulating layer GI may be 80 nm, 100 nm, 115 nm, 130 nm, or 150 nm, etc., which will not be listed one by one in the embodiments of the present disclosure.

In some embodiments, referring to FIG. 9, FIG. 10 and FIG. 13, the first transistor T1 and the second transistor T2 are both oxide thin-film transistors, and based on this, the array substrate may be formed by using the oxide thin-film transistors entirely, which is conducive to reducing the manufacturing difficulty and manufacturing cost of the array substrate.

The manufacturing process of the oxide thin-film transistors has a lower temperature (compared to the LTPS process), and based on this, in some embodiments, referring to FIG. 9 and FIG. 13, the array substrate 100 may also include a lens structure 40 and a third planar layer SOG. The lens structure 40 is disposed on a side of the first transistor T1 near the base 11, and for example, disposed on a side of the first signal line DL near the base 11. The lens structure 40 is configured to converge light emitted towards the lens structure 40, which is conducive to enhancing light emitted towards the pixel area 101, thereby improving the light transmittance of the array substrate. A lens structure 40 covers at least a pixel area 101.

The third planar layer SOG is disposed between the lens structure 40 and the first transistor T1, and exemplarily, the third planar layer SOG is disposed between the lens structure 40 and the first signal line DL. The refractive index of the lens structure 40 is greater than the refractive index of the third planar layer SOG. On one hand, the third planar layer SOG may improve the flatness of a plane in which the first signal line DL is located, and reduce the shape and size errors of the first signal line DL. On the other hand, light emitted from the lens structure 40 towards the third planar layer SOG may be refracted at an intersected interface between the lens structure 40 and the third planar layer SOG, which is conducive to the light convergence and increasing the light intensity in a central area of the pixel area 101, and conducive to improving the light transmittance of the array substrate.

Exemplarily, a surface of the lens structure 40 away from the base 11 may be an arcuate surface. For example, the aforementioned surface is an arcuate surface that protrudes towards a side of a center of the lens structure 40 away from the base 11.

In some embodiments, the refractive index of the lens structure 40 is 1.8 to 2.3; and/or, the refractive index of the third planar layer SOG is 1.3 to 1.5. In this way, it is beneficial for the light emitted from the lens structure 40 towards the third planar layer SOG to be refracted at the intersected interface between the lens structure 40 and the third planar layer SOG, so that the light converges towards the central area of the pixel area 101, which is conducive to enhancing the light intensity in the central area of the pixel area 101, and conducive to improving the light transmittance of the display panel. Exemplarily, the refractive index of the lens structure 40 may be 1.8, 1.9, 2.0, 2.1, 2.2, or 2.3, etc.; the refractive index of the third planar layer SOG may be 1.3, 1.4, 1.45, or 1.5, etc., which will not be listed one by one in the embodiments of the present disclosure.

In some embodiments, along a direction perpendicular to the base 11 (the third direction Z), the thickness (the maximum thickness) of the lens structure 40 is 800 nm to 1500 nm; and/or, the thickness of the third planar layer SOG is 1.5 μm to 2.5 μm. Exemplarily, the thickness of the lens structure 40 is 800 nm, 900 nm, 1000 nm, 1250 nm, 1400 nm, or 1500 nm, etc.; the thickness of the third planar layer SOG may be 1.5 μm, 1.7 μm, 1.9 μm, 2.0 μm, 2.3 μm, or 2.5 μm, etc., which will not be listed one by one in the embodiments of the present disclosure.

The lens structure 40 may be formed by using a transparent material, to enhance the transmittance of the lens structure 40, and improve the transmittance of the array substrate 100. Exemplarily, the transparent material includes but is not limited to silicon nitride SiNx and niobium oxide (such as niobium pentoxide, Nb₂O₅). The material of the third planar layer SOG may include but not be limited to a silicon-glass bonded structure (Silicon On Glass; abbreviated as: SOG) material.

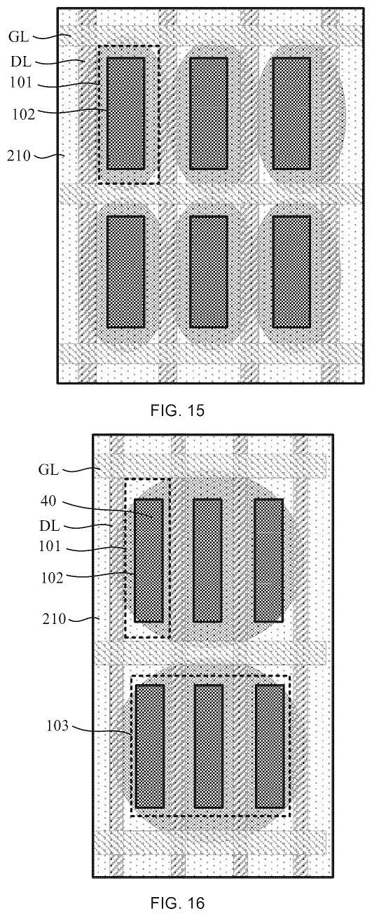

In some embodiments, referring to FIG. 15 and FIG. 16, the array substrate 100 includes multiple opening areas 102, and it should be noted that, the opening area 102 is an area that is located within the pixel area 101 and used to form an actual light-emitting area of a sub-pixel. For example, the opening area 102 may be an area covered by an orthographic projection of the opening of the black matrix 210 on the color film substrate onto the array substrate 100.

In some embodiments, referring to FIG. 15, a lens structure 40 covers an opening area 102. In this way, it is conducive to increasing the light transmittance of each opening area 102 accurately. And/or, referring to FIG. 16, the array substrate 100 includes multiple pixel units 103, and the pixel unit 103 includes at least two opening areas 102 that emit different light. In this way, the convergence of light within a pixel unit 103 to the center of the pixel unit 103 may be improved.

Exemplarily, a lens structure 40 covers all opening areas 102 of a pixel unit 103. For example, referring to FIG. 16, the pixel unit 103 includes three opening areas 102, the three opening areas 102 are configured to emit red light, green light, and blue light respectively, and a lens structure 40 covers three opening areas 102 included in a pixel unit 103.

In some embodiments, referring to FIG. 15 and FIG. 16, an orthographic projection of the lens structure 40 on the base 11 overlaps at least partially with an orthographic projection of at least one of the first signal line DL and the second signal line GL on the base 11, which may significantly increase the size of the lens structure 40, so as to facilitate the convergence of more light into the opening area 102, thereby significantly improving the brightness of the opening area 102, and improving the luminance brightness of the array substrate 100.

In some embodiments, referring to FIG. 15 and FIG. 16, the pixel area 101 in the first direction X has a smaller size than in the second direction Y, and an interval between two adjacent pixel areas 101 along the first direction X is less than an interval between two adjacent pixel areas 101 along the second direction Y. Based on this, along the first direction X, two adjacent lens structures 40 are connected with each other. And/or, along the second direction Y, there is an interval between two adjacent lens structures 40. In this way, it is conducive to maximizing the size of the lens structure 40 and reducing the likelihood of the convergence of light to an area outside the opening area 102, and conducive to improving the transmittance of the opening area 102.

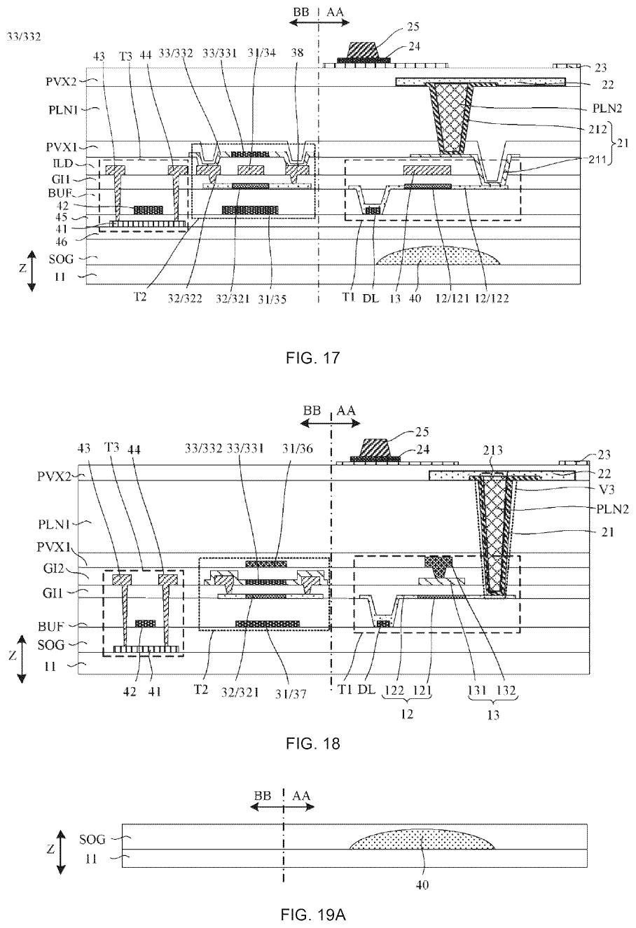

In some embodiments, referring to FIG. 17 and FIG. 18, the array substrate 100 also includes a third transistor T3, and the third transistor T3 is disposed on a side of the first transistor T1 near the base 11 and disposed within the peripheral area BB. Exemplarily, the third transistor T3 is configured to form a gate driving circuit (Gate on Array; abbreviated as GOA). The third transistor T3 includes a fourth semiconductor pattern 41 and a third electrode structure 42, and the third electrode structure 42 is located on a side of the fourth semiconductor pattern 41 away from the base 11. Here, the fourth semiconductor pattern 41 and the first semiconductor pattern 12 include different semiconductor materials.

In some embodiments, the third transistor T3 may be a low-temperature poly silicon thin-film transistor (Low Temperature Poly Silicon Thin-Film Transistor, abbreviated as LTPS TFT), and the low-temperature poly silicon thin-film transistor has advantages such as high mobility, high response speed, etc., which is conducive to improving the response speed of the gate driving circuit.

The gate driving circuit may include both the third transistor T3 and the second transistor T2, that is, the gate driving circuit may form a complementary metal oxide semiconductor (CMOS) circuit. In this way, it is conducive to further reducing the space occupied by the gate driving circuit, and reducing the width of the peripheral area, and conducive to achieving a narrow border for the array substrate and the display apparatus. Meanwhile, the gate driving circuit with the CMOS architecture is conducive to reducing the power consumption of the gate driving circuit, thereby reducing the power consumption of the array substrate.

Referring to FIG. 17 and FIG. 18, in a case where the first signal line DL is disposed on a side of the first semiconductor pattern 12 near the base 11, the third electrode structure 42 of the third transistor T3 may include the same material and be disposed on the same layer as the first signal line DL, that is, the first signal line DL may be formed in the same patterning process by using the same mask and/or using the same material as the third electrode structure 42. In this way, it is conducive to simplifying the manufacturing process of the third electrode structure 42, simplifying the manufacturing process and manufacturing difficulty of the array substrate, and reducing the manufacturing cost of the array substrate.

In some embodiments, referring to FIG. 17 and FIG. 18, the fourth transistor T4 may also include a first pole 43 and a second pole 44, one of the first pole 43 and the second pole 44 may be a source, and another of them may be a drain. Referring to FIG. 17, the array substrate 100 may also include a second buffer layer 45 located between the fourth semiconductor pattern 41 and the third planar layer SOG, as well as an inter-layer gate dielectric layer 46 located between the fourth semiconductor pattern 41 and the third electrode structure 42.

In some embodiments, referring to FIG. 17 and FIG. 18, the array substrate 100 may also include a fourth insulating layer PVX2 between the first electrode 22 and the second electrode 23, a light-shielding layer 24 located on a side of the second electrode 23 away from the base 11, and a photo spacer (PS) 25 located on a side of the light-shielding layer 24 away from the base 11.

Exemplarily, an orthographic projection of the second electrode 23 on the base 11 covers an orthographic projection of the light-shielding layer 24 on the base 11, and the line width of the light-shielding layer 24 is less than the line width of the second electrode 23; the orthographic projection of the light-shielding layer 24 on the base 11 also covers an orthographic projection of the photo spacer 25 on the base 11, and the line width of the photo spacer 25 is less than the line width of the light-shielding layer 24.

Exemplarily, the light-shielding layer 24 may use a blackened metal material, the blackened metal material may be a metal material with a light-shielding ratio greater than a second threshold, and the second threshold may be, for example, 80%, 85%, 90%, or 95%, etc., which will not be listed one by one in the embodiments of the present disclosure. The blackened metal material includes but is not limited to at least one of molybdenum (Mo), aluminum (Al), molybdenum niobium (MoNb), and molybdenum nickel titanium (MTD). The photo spacer 25 may use an inorganic material and/or an organic material, where the inorganic material may include one or more of metal oxide and the blackened metal material; and the metal oxide may include but be not limited to silicon nitride, silicon oxide, titanium nitride, molybdenum nitride, molybdenum oxide, niobium oxide, niobium nitride, etc. The light-shielding layer 24 and the photo spacer 25 may be formed by a mask process, and for example, by wet etching plus dry etching, and a stepped shape is formed between the light-shielding layer 24 and the photo spacer 25, by utilizing the difference of the etch bias of the photo spacer 25 and the light-shielding layer 24.

Exemplarily, the thickness of the light-shielding layer 24 may be 30 nm to 80 nm, and the thickness of the photo spacer 25 may be 0.4 μm to 1 μm. Here, on one hand, the light-shielding layer 24 may be used to shield the first signal line DL and the second signal line GL, and on the other hand, it may reduce the electrical connection with the second electrode 23, for transmitting voltage signals to the second electrode 23, and is disposed in parallel with the second electrode 23, which is conducive to reducing the resistance of the second electrode 23.

The photo spacer 25 is configured to support the array substrate 100 and the color film substrate, and is used to maintain the support of the liquid crystal box thickness between the array substrate 100 and the color film substrate. Of course, the structure of the array substrate 100 is not limited to this, as long as the same technical idea is used.

In some embodiments, referring to FIG. 3A, the extending direction of the first signal line DL may be a straight line. The array substrate 100 includes multiple first semiconductor patterns 12, and the extending direction of the first semiconductor pattern 12 may form a certain angle with the second direction, which is conducive to increasing the direct opposite area between the first semiconductor pattern 12 and the first electrode structure 13, increasing the width of the first channel area 121, and improving the characteristic of the first transistor T1. Moreover, the multiple first semiconductor patterns 12 are arranged in multiple rows, and tilt directions of the multiple rows of first semiconductor patterns 12 are the same.

In some other embodiments, referring to FIG. 3B, the extending direction of the first signal line DL may be a broken line. The array substrate 100 includes multiple first semiconductor patterns 12, and the extending direction of the first semiconductor pattern 12 may form a certain angle with the second direction, which is conducive to increasing the direct opposite area between the first semiconductor pattern 12 and the first electrode structure 13, increasing the width of the first channel area 121, and improving the characteristic of the first transistor T1. Moreover, the multiple first semiconductor patterns 12 are arranged in multiple rows, and two adjacent rows of first semiconductor patterns 12 have opposite tilt directions, as shown in FIG. 3B, the first semiconductor pattern 12 in a first row tilts to the right from top to bottom, and the first semiconductor pattern 12 in a second row tilts to the left from top to bottom.

It may be understood that the shape and extending direction of the first semiconductor pattern 12 are not limited to the aforementioned embodiments, and for example, in a case where the first signal line DL extends along the broken line (as shown in FIG. 3B), the first semiconductor pattern 12 may also extend along the second direction Y. Alternatively, in a case where the first signal line DL extends along the straight line (as shown in FIG. 3A), the first semiconductor pattern 12 may extend along the broken line, and includes, for example, a part extending along the first direction and a part extending along the second direction. The embodiments of the present disclosure are not limited thereto, as long as the same technical idea is used.

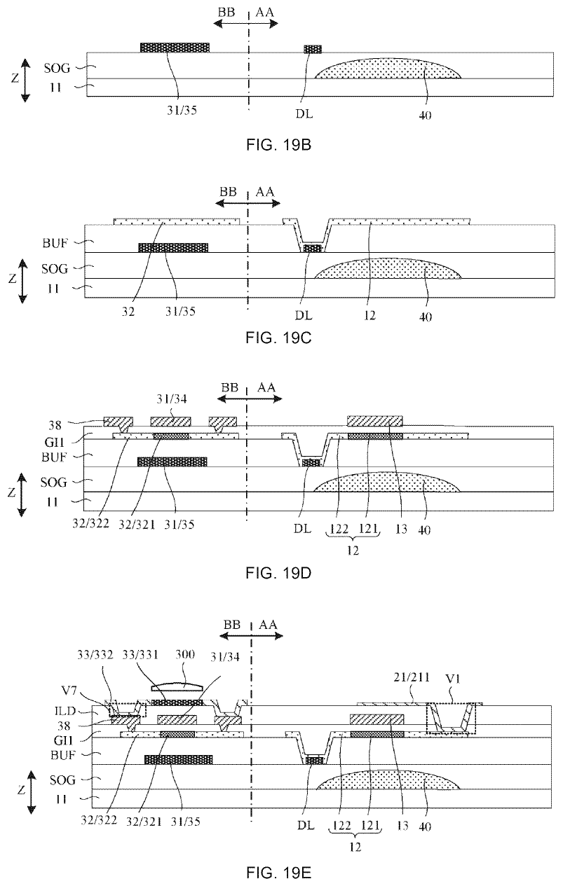

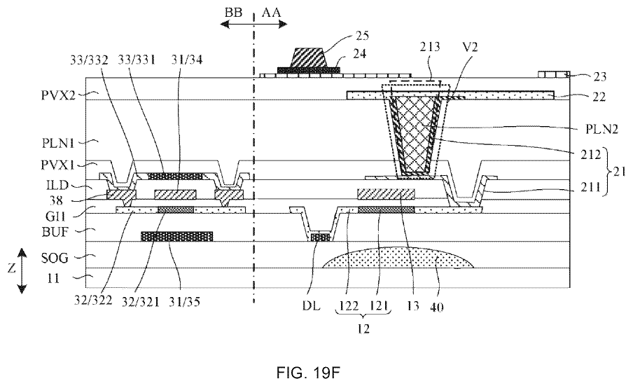

The embodiments of the present disclosure also provide a manufacturing method for the array substrate, and by taking manufacturing the array substrate as shown in FIG. 9 as an example, the embodiments of the present disclosure are described exemplarily. As shown in FIG. 19A to FIG. 19D, the manufacturing method for the array substrate may include S100 to S500.

S100, referring to FIG. 19A, the lens structure 40 and the third planar layer SOG are manufactured on the base 11.

Exemplarily, the material of the lens structure 40 may include a transparent material with a high refractive index (compared to the third planar layer SOG), and for example, the material of the lens structure 40 may include but be not limited to silicon nitride (SiNx) or niobium oxide (such as niobium pentoxide Nb₂O₅). Exemplarily, an initial material layer with a thickness of 800 nm to 1500 nm may be manufactured first, and then lithography and etch processes are performed on the initial material layer, to manufacture and form the lens structure 40.

Exemplarily, the third planar layer SOG may use a transparent material with a low refractive index (compared to the lens structure 40), and the third planar layer SOG needs to tolerate a certain high-temperature environment, to avoid the deformation of the third planar layer SOG during the manufacturing of the first semiconductor pattern 12. For example, the material of the third planar layer SOG may include but not be limited to a silicon-glass bonded structure (Silicon On Glass; abbreviated as: SOG) material. The thickness of the third planar layer SOG may be 1.5 μm to 2.5 μm.

S200, referring to FIG. 19B, the first conductive layer is formed on the third planar layer SOG.

For example, the first conductive layer may include the first signal line DL located within the display area AA, and the second sub-electrode 35 or the fourth sub-electrode 37 of the second electrode structure 31 located in the peripheral area. The material of the first conductive layer may include a metallic material, such as including one or more of metal titanium, aluminum, copper, molybdenum, niobium, nickel and their alloys, or the first conductive layer may also be a metal-stacked layer structure. Exemplarily, the first conductive layer may include one or any combination of: a titanium-aluminum-titanium (Ti/Al/Ti) stacked layer structure, molybdenum-aluminum (Mo/Al) stacked layer structure, molybdenum-aluminum-molybdenum (Mo/Al/Mo) stacked layer structure, molybdenum-niobium-titanium (MoNb/Ti) stacked layer structure, molybdenum niobium-titanium-copper (MoNb/Ti/Cu) stacked layer structure, molybdenum niobium-copper (MoNb/Cu) stacked layer structure, molybdenum nickel titanium-copper (MTD/Cu) stacked layer structure, molybdenum niobium-copper-molybdenum-titanium-nickel (MoNb/Cu/MTD) stacked layer structure, molybdenum nickel titanium-copper-molybdenum nickel titanium (MTD/Cu/MTD) stacked layer structure, molybdenum-neodymium-copper stacked layer structure, MoNb-copper-MoNb stacked layer structure, and AlNb-molybdenum-AlNd stacked layer structure. Of course, the embodiments of the present disclosure are not limited thereto, and the first conductive layer may also consider any other suitable metal or metal stacked layer structures.

Exemplarily, a whole layer of a metal material layer may be first formed on the third planar layer SOG, and then the metal material layer is patterned by using lithography and etch processes, to obtain the first signal line DL, and the second sub-electrode 35 or the fourth sub-electrode 37 of the second electrode structure 31.

S300, referring to FIG. 19C, the buffer layer BUF and the first semiconductor layer are manufactured on a side of the first conductive layer away from the base 11.

Exemplarily, the material of the buffer layer BUF may include silicon oxide (SiOx, x>0), and the value of x may be 1 or 2. Alternatively, the material of the buffer layer BUF may also include silicon nitride (SiNy, y>0), and the value of y may be 1 or 2, such as SiN and SiN1.33. The buffer layer BUF may be a single-layer or stacked-layer structure, and for example, the buffer layer BUF is a stacked-layer structure including silicon oxide and silicon nitride. In addition, the thickness of the buffer layer BUF may be 200 nm to 500 nm, and exemplarily, the thickness of the buffer layer BUF may be 200 nm, 300 nm, 450 nm, or 500 nm, etc., which will not be listed one by one in the embodiments of the present disclosure.

Exemplarily, a film layer deposition process may be used to manufacture and form a whole layer of the buffer layer BUF, and then the fourth via-hole V4 may be manufactured and formed on the buffer layer BUF by using lithography and etching processes, and the fourth via-hole V4 may expose a part area of the first signal line DL.

The material of the first semiconductor layer refers to the material of the above first semiconductor pattern 12, which will not be repeated here. The first semiconductor layer may include the first semiconductor pattern 12 located in the display area AA and the second semiconductor pattern 32 located in the peripheral area BB. Here, at least a part of the first semiconductor pattern 12 is located within the fourth via-hole V4 and contacts with the first signal line DL.

S400, referring to FIG. 19D, the first insulating layer GI1 and the gate line layer are manufactured and formed in sequence on a side of the first semiconductor layer away from the base 11.

Exemplarily, the material of the first insulating layer GI1 may include an insulating material, and for example, the insulating material may include but not be limited to aluminum oxide (Al₂O₃), silicon oxide (SiOx, x>0), and the value of x may be 1 or 2. Here, the first insulating layer GI1 includes a via-hole located in the peripheral area BB, and the via-hole exposes a part area of the second semiconductor pattern 32.

Exemplarily, the gate line layer may include a first electrode structure 13 located in the display area AA, and a first sub-electrode 34 of a second electrode structure 31 located at the peripheral area BB, and an adaptor pattern 38, and the adaptor pattern 38 is connected to the second semiconductor pattern 32 through the via-hole located at the first insulating layer GI1 mentioned above.

S500, after manufacturing and forming the gate line layer, a patterning process may be performed on a part area of the first semiconductor layer, by using a process including but not limited to ion implantation, ion bombardment, etc., and an annealing process, etc., so that a part of the first semiconductor pattern 12 and a part of the second semiconductor pattern 32 are made conductive and the other parts are kept as the semiconductor material.

S600, referring to FIG. 19E, the second insulating layer ILD and the second semiconductor layer are manufactured in sequence on a side of the gate line layer away from the base 11.

Exemplarily, the material of the second insulating layer ILD includes but is not limited to silicon oxide, silicon nitride (SiNy, y>0) and aluminum oxide, etc.

Exemplarily, the manufacturing process of the second insulating layer ILD may include: forming a whole layer of a second insulating film, performing lithography and etch on the second insulating film, to form the first via-hole V1 in the display area and form a seventh via-hole V7 in the peripheral area that exposes an adaptor pattern 38. Here, the depth of the seventh via-hole V7 is less than the depth of the first via-hole V1, and based on this, the adaptor pattern 38, that serves as a stop layer for the seventh via-hole V7, needs to tolerate a certain overetch.

The material of the second semiconductor layer refers to the material of the third semiconductor pattern 33 mentioned above, and will not be repeated here.

Exemplarily, the manufacturing process of the second semiconductor layer may include: forming the second semiconductor layer with a certain pattern, where the second semiconductor layer includes a first sub-connecting electrode 211 located in the display area AA and a third semiconductor pattern 33 located in the peripheral area BB.

After forming the second semiconductor layer, a mask layer 400 needs to be formed on the second semiconductor layer, and the mask layer 400 covers a part area of the third semiconductor pattern 33, and exposes a part area of the third semiconductor pattern 33 and exposes the first sub-connecting electrode 211. Then, by using the mask layer 400 as a mask, an area in the third semiconductor layer that is not covered by the mask layer 400 is made conductive, so that the third semiconductor pattern 33 forms a third channel area 331 and two third pole areas 332, and the first sub-connecting electrode 211 is made conductive.

S700, referring to FIG. 19F, a third insulating layer PVX1, a first planar layer PLN1, a second sub-connecting electrode 212, a second planar layer PLN2, a first electrode 22, a fourth insulating layer PVX2, a second electrode 23, a common voltage signal line CM and a photo spacer PS, etc., are formed in sequence on a side of the second semiconductor layer away from the base 11.

The structures of the third insulating layer PVX1, the first planar layer PLN1, the second sub-connecting electrode 212, the second planar layer PLN2, the first electrode 22, the fourth insulating layer PVX2, the second electrode 23, the light-shielding layer 24 and the photo spacer 25 refer to the above content and will not be repeated here again.

The above description is merely the specific implementation of the present disclosure, but the protection scope of the present disclosure is not limited thereto. All changes or substitutions that any person skilled in this art who is familiar with this technology field may think of within the technical scope disclosed by the present disclosure, should be covered within the protection scope of the present disclosure. Therefore, the protection scope of the present disclosure should be based on the protection scope of the stated claims.

1. An array substrate, having a display area and a peripheral area located at a periphery of the display area; wherein the array substrate further comprises:
a base;
a first transistor, disposed on a side of the base and disposed in the display area; wherein the first transistor comprises a first semiconductor pattern and a first electrode structure disposed on a side of the first semiconductor pattern away from the base;
a connecting electrode, disposed on a side of the first electrode structure away from the base, and electrically connected to the first semiconductor pattern;
a first electrode, disposed on a side of the connecting electrode away from the base, and electrically connected to the connecting electrode; and
a second electrode, disposed on a side of the first electrode away from the base;
wherein at least one of the connecting electrode and the first electrode structure comprises a semiconductor material.

2. The array substrate according to claim 1, wherein the array substrate further comprises:
a second transistor, located on a same side of the substrate as the first transistor, and disposed in the peripheral area, wherein the second transistor comprises a second semiconductor pattern and a third semiconductor pattern; wherein:
the second semiconductor pattern comprises a second channel area and two second pole areas located on two opposite sides of the second channel area;
the third semiconductor pattern comprises a third channel area and two third pole areas located on two opposite sides of the third channel area; and
the second channel area and the third channel area have an interval in a direction perpendicular to the base, and an orthographic projection of the second channel area on the base at least partially overlaps with an orthographic projection of the third channel area on the base; and a second pole area and a third pole area, that are located on a same side of the second channel area and the third channel area, are electrically connected.

3. The array substrate according to claim 2, wherein
the second semiconductor pattern comprises a same material and is disposed on a same layer as the first semiconductor pattern; and/or the third semiconductor pattern comprises a same material and is disposed on a same layer as one of the connecting electrode and the first electrode structure which comprises the semiconductor material; or
the second semiconductor pattern comprises a same material and is disposed on a same layer as the first semiconductor pattern; and/or the third semiconductor pattern comprises a same material and is disposed on a same layer as one of the connecting electrode and the first electrode structure which comprises the semiconductor material; and the second transistor further comprises a second electrode structure, and the second electrode structure is disposed at least partially opposite to the second channel area, and disposed at least partially opposite to the third channel area; or
the second semiconductor pattern comprises a same material and is disposed on a same layer as the first semiconductor pattern; and/or the third semiconductor pattern comprises a same material and is disposed on a same layer as one of the connecting electrode and the first electrode structure which comprises the semiconductor material; and the second transistor further comprises a second electrode structure, and the second electrode structure is disposed at least partially opposite to the second channel area, and disposed at least partially opposite to the third channel area; and the connecting electrode comprises the semiconductor material, and the third semiconductor pattern comprises a same material and is disposed on a same layer as the connecting electrode.

4. (canceled)

5. (canceled)

6. The array substrate according to claim 3, wherein
the second electrode structure comprises a first sub-electrode disposed between the second semiconductor pattern and the third semiconductor pattern; the first sub-electrode is disposed opposite to the second channel area and the third channel area respectively, and an orthographic projection of the first sub-electrode on the base at least partially overlaps with projections of the second channel area and the third channel area on the base respectively; or
the second electrode structure comprises a first sub-electrode disposed between the second semiconductor pattern and the third semiconductor pattern; the first sub-electrode is disposed opposite to the second channel area and the third channel area respectively, and an orthographic projection of the first sub-electrode on the base at least partially overlaps with projections of the second channel area and the third channel area on the base respectively; and the first sub-electrode comprises a same material and is disposed on a same layer as the first electrode structure; or
the second electrode structure comprises a first sub-electrode disposed between the second semiconductor pattern and the third semiconductor pattern; the first sub-electrode is disposed opposite to the second channel area and the third channel area respectively, and an orthographic projection of the first sub-electrode on the base at least partially overlaps with projections of the second channel area and the third channel area on the base respectively; and the second transistor further comprises at least one adaptor pattern, and the adaptor patter is disposed between the second pole area and the third pole area that are close to each other, and electrically connected to the second pole area and the third pole area respectively, and the adaptor pattern comprises a same material and is disposed on a same layer as the first sub-electrode.

7. (canceled)

8. (canceled)

9. The array substrate according to claim 6, wherein
the second electrode structure further comprises a second sub-electrode disposed on a side of the second semiconductor pattern near the base, the second sub-electrode is disposed opposite to the second channel area, and an orthographic projection of the second sub-electrode on the base at least partially overlaps with an orthographic projection of the second channel area on the base.

10. The array substrate according to claim 9, wherein
the orthographic projection of the second sub-electrode on the base covers orthographic projections of the second channel area and the third channel area on the base, and partially overlaps with an orthographic projection of at least one of the two second pole areas and the two third pole areas on the base; and
the orthographic projection of the second sub-electrode on the base further covers an orthographic projection of the first sub-electrode on the base, and a boundary of the orthographic projection of the second sub-electrode has an interval with a boundary of the orthographic projection of the first sub-electrode; or
the display area further comprises a first signal line, and the first signal line is disposed on a side of the first semiconductor pattern near the base; the first semiconductor pattern comprises a first channel area and two first pole areas located on two opposite sides of the first channel area, one of the two first pole areas is electrically connected to the connecting electrode, and another of the two first pole areas is electrically connected to the first signal line; and the first signal line comprises a same material and is disposed on a same layer as the second sub-electrode.

11. (canceled)

12. The array substrate according to claim 3, wherein
the connecting electrode comprises a first sub-connecting electrode and a second sub-connecting electrode, the second sub-connecting electrode is located on a side of the first sub-connecting electrode away from the base;
the array substrate further comprises:
a first insulating layer, disposed between the first semiconductor pattern and the first electrode structure;
a second insulating layer, disposed between the first electrode structure and the first sub-connecting electrode;
a first via-hole, passing through the second insulating layer and the first insulating layer, and exposing a part area of the first semiconductor pattern;
a first planar layer, disposed between the first sub-connecting electrode and the second sub-connecting electrode;
a second via-hole, passing through the first planar layer; and
a second planar layer, disposed between the second sub-connecting electrode and the first electrode;
wherein the first sub-connecting electrode comprises a first portion and a second portion, the first portion passes through the first via-hole to electrically connect with the first semiconductor pattern, the second portion is located on a surface of the second insulating layer away from the base; the second via-hole exposes at least a part of the second portion, the second sub-connecting electrode passes through the second via-hole to connect with the second portion, a part of the second sub-connecting electrode located within the second via-hole comprises a slot recessed towards a side near the base; the second planar layer is disposed within the slot, and a surface of the second planar layer away from the base is roughly flush with a surface of the second sub-connecting electrode away from the base; and
the third semiconductor pattern comprises a same material and is disposed on a same layer as the first sub-connecting electrode.

13. The array substrate according to claim 3, wherein
the first electrode structure comprises an auxiliary electrode and an electrode portion, the electrode portion is located on a side of the auxiliary electrode away from the base, a material of the auxiliary electrode comprises a semiconductor material, and the third semiconductor pattern comprises a same material and is disposed on a same layer as the auxiliary electrode.

14. The array substrate according to claim 13, wherein
the second electrode structure comprises a third sub-electrode disposed on a side of the third semiconductor pattern away from the base, and a fourth sub-electrode disposed on a side of the second semiconductor pattern near the base; the third sub-electrode is disposed opposite to the third semiconductor pattern, and an orthographic projection of the third sub-electrode on the base at least partially overlaps with an orthographic projection of the third channel area on the base; and the fourth sub-electrode is disposed opposite to the second semiconductor pattern, and an orthographic projection of the fourth sub-electrode on the base at least partially overlaps with an orthographic projection of the second channel area on the base; or
the second electrode structure comprises a third sub-electrode disposed on a side of the third semiconductor pattern away from the base, and a fourth sub-electrode disposed on a side of the second semiconductor pattern near the base; the third sub-electrode is disposed opposite to the third semiconductor pattern, and an orthographic projection of the third sub-electrode on the base at least partially overlaps with an orthographic projection of the third channel area on the base; and the fourth sub-electrode is disposed opposite to the second semiconductor pattern, and an orthographic projection of the fourth sub-electrode on the base at least partially overlaps with an orthographic projection of the second channel area on the base; and the third sub-electrode comprises a same material and is disposed on a same layer as the electrode portion.

15. (canceled)

16. The array substrate according to claim 1, wherein
the display area further comprises a first signal line, the first signal line is disposed on a side of the first semiconductor pattern near the base;
the first semiconductor pattern comprises a first channel area and two first pole areas located on two opposite sides of the first channel area, one of the two first pole areas is electrically connected to the connecting electrode, and another of the two first pole areas is electrically connected to the first signal line; and
the first signal line comprises a same material and is disposed on a same layer as the fourth sub-electrode.

17. The array substrate according to claim 13, wherein a third insulating layer is comprised between the auxiliary electrode and the electrode portion;
the auxiliary electrode and the electrode portion are electrically connected in the display area, and/or the auxiliary electrode and the electrode portion are electrically connected in the peripheral area; or
a third insulating layer is comprised between the auxiliary electrode and the electrode portion; the auxiliary electrode and the electrode portion are electrically connected in display area, and/or the auxiliary electrode and the electrode portion are electrically connected in the peripheral area; and the array substrate further comprises:
a first insulating layer, disposed between the first semiconductor pattern and the first electrode structure;
a second insulating layer and a first planar layer, disposed between the first electrode structure and the connecting electrode, wherein the first planar layer is located away from a side of the base, compared to the second insulating layer;
a third via-hole, passing through the first planar layer, the second insulating layer, the third insulating layer and the first insulating layer, and exposing a part area of the first semiconductor pattern; and
a second planar layer, disposed between the connecting electrode and the first electrode;
wherein the connecting electrode comprises a third portion and a fourth portion, the third portion passes through the third via-hold to electrically connect with the first semiconductor pattern, the fourth portion is located on a surface of the first planar layer away from the base and electrically connected to the first electrode; the third portion comprises a slot recessed towards a side near the base, the second planar layer is disposed within the slot, and a surface of the second planar layer away from the base is roughly flush with a surface of the fourth portion away from the base.

18. (canceled)

19. The array substrate according to claim 2, wherein
the second semiconductor pattern and the third semiconductor pattern both comprise a metal oxide semiconductor material; and
electron mobility of the second semiconductor pattern is greater than electron mobility of the third semiconductor pattern, and light stability of the third semiconductor pattern is greater than light stability of the second semiconductor pattern.

20. The array substrate according to claim 19, wherein
the second semiconductor pattern comprises a high-mobility metal oxide semiconductor material; and/or
the third semiconductor pattern comprises indium gallium zinc oxide.

21. The array substrate according to claim 1, wherein
the array substrate further comprises: a third transistor, disposed on a side of the first transistor near the base and disposed in the peripheral area; wherein the third transistor comprises a fourth semiconductor pattern and a third electrode structure, the third electrode structure is located on a side of the fourth semiconductor pattern away from the base; wherein the fourth semiconductor pattern and the first semiconductor pattern comprise different semiconductor materials; or
the array substrate further comprises: a first signal line, disposed in the display area and disposed on a side of the first semiconductor pattern near the base; a buffer layer, disposed between the first signal line and the first semiconductor pattern; and a fourth via-hole, passing through the buffer layer, and exposing a part of the first signal line; wherein a part of the first semiconductor pattern is located within the fourth via-hole and passes through the fourth via-hole to electrically connect with the first signal line; or
the array substrate further comprises: a first signal line, disposed in the display area and disposed on a side of the first semiconductor pattern near the base; a buffer layer, disposed between the first signal line and the first semiconductor pattern; and a fourth via-hole, passing through the buffer layer, and exposing a part of the first signal line; wherein a part of the first semiconductor pattern is located within the fourth via-hole and passes through the fourth via-hole to electrically connect with the first signal line; and in a case where the array substrate comprises a third transistor, a third electrode structure comprises a same material and is disposed on a same layer as the first signal line.

22. The array substrate according to claim 21, wherein
the first transistor is an oxide thin-film transistor; and/or
the third transistor is a low-temperature poly silicon thin-film transistor.

23. (canceled)

24. The array substrate according to claim 21, wherein
the fourth via-hole exposes two opposite sidewalls of the first signal line, and an orthographic projection of the first semiconductor pattern on the base covers at least a half of an orthographic projection of the fourth via-hole on the base; or
the buffer layer comprises a first sub-layer and a second sub-layer stacked along a direction away from the base; a material of the first sub-layer comprises silicon nitride, and a material of the second sub-layer comprises silicon oxide.

25. (canceled)

26. The array substrate according to claim 24, wherein
a thickness of the first sub-layer is greater than or equal to 50 nm; and/or
the array substrate further comprises a first insulating layer, and the first insulating layer is disposed between the first semiconductor pattern and the first electrode structure, and a thickness of the first insulating layer is 80 nm to 150 nm.

27. (canceled)

28. The array substrate according to claim 1, wherein the array substrate further comprises:
multiple opening areas, wherein an opening area of the multiple opening area is configured to form a light-emitting area of a sub-pixel;
multiple lens structures, disposed on a side of the first transistor near the base, wherein a lens structure of the multiple lens structures is configured to converge light emitted towards the lens structure; a lens structure of the multiple lens structures covers at least one of the multiple opening areas; and
a third planar layer, disposed between the lens structure and the first transistor;
wherein a refractive index of the lens structure is greater than a refractive index of the third planar layer.

29. The array substrate according to claim 28, wherein
the refractive index of the lens structure is 1.8 to 2.3; and/or the refractive index of the third planar layer is 1.3 to 1.5; or
a thickness of the lens structure is 800 nm to 1500 nm; and/or a thickness of the third planar layer is 1.5 μm to 2.5 μm.

30. (canceled)

31. The array substrate according to claim 28, wherein
a lens structure of the multiple lens structures covers an opening area of the multiple opening areas; and/or the array substrate comprises multiple pixel units, a pixel unit of the multiple pixel units comprises at least two opening areas for emitting different light; and a lens structure of the multiple lens structures covers the at least two opening areas of a pixel unit of the multiple pixel unit; or
a lens structure of the multiple lens structures covers an opening area of the multiple opening areas; and/or the array substrate comprises multiple pixel units, a pixel unit of the multiple pixel units comprises at least two opening areas for emitting different light; and a lens structure of the multiple lens structures covers the at least two opening areas of a pixel unit of the multiple pixel units; and an orthographic projection of the lens structure on the base at least partially overlaps with an orthographic projection of a first signal line on the base; or
a lens structure of the multiple lens structures covers an opening area of the multiple opening areas; and/or the array substrate comprises multiple pixel units, a pixel unit of the multiple pixel units comprises at least two opening areas for emitting different light; and a lens structure of the multiple lens structures covers the at least two opening areas of a pixel unit of the multiple pixel units; and an orthographic projection of the lens structure on the base at least partially overlaps with an orthographic projection of a first signal line on the base; and along a first direction, two adjacent lens structures of the multiple lens structures are connected to each other, and/or along a second direction, there is an interval between two adjacent lens structures of the multiple lens structures.

32. (canceled)

33. (canceled)
